(19) United States
(12) Patent Application Publication
(10) Pub. No.: US 2020/0083416 A1
(43) Pub. Date: Mar. 12, 2020

(54) METHOD FOR PREPARING AN OPTOELECTRONIC DEVICE FROM A CROSSLINKABLE POLYMER COMPOSITION

(71) Applicant: MERCK PATENT GMBH, Darmstadt (DE)

(72) Inventors: Ralf GROTTENMUELLER, Wiesbaden (DE); Casas Abraham GARCIA-MINGUILLAN, Wiesbaden (DE); Fumio KITA, Wiesbaden (DE)

(73) Assignee: MERCK PATENT GMBH, Darmstadt (DE)

(21) Appl. No.: 16/466,197

(22) PCT Filed: Nov. 30, 2017
(86) PCT No.: PCT/EP2017/080910

§ 371 Date: Jun. 3, 2019

(30) Foreign Application Priority Data
Dec. 2, 2016 (EP) 16201984.8

(51) Int. Cl. H01L 33/56; C08G 77/62; C09D 183/16; C08G 77/12

(52) U.S. Cl. CPC H01L 33/56; C08G 77/62; H01L 2933/005; C08G 77/12; C09D 183/16

(57) ABSTRACT

The present invention relates to a method for preparing an optoelectronic device comprising a crosslinked polymer material which is prepared from a crosslinkable polymer formulation comprising a polymer with a silazane repeating unit M¹ and a Lewis acid curing catalyst. There is further provided a crosslinkable polymer formulation comprising a siloxazane polymer which is particularly suitable for the preparation of technical coatings on articles.

### TECHNICAL FIELD

The present invention relates to a method for preparing an optoelectronic device comprising a crosslinked polymer material which is prepared from a crosslinkable polymer formulation comprising a polymer with a silazane repeating unit M¹ and a Lewis acid curing catalyst. The Lewis acid curing catalyst catalyzes the crosslinking of the polymer in the crosslinkable polymer composition to obtain a crosslinked polymer material. In particular, the curing catalyst allows a fast and complete crosslinking of polymers having silazane repeating units to prepare crosslinked silazane based polymer materials under mild conditions, such as at moderate temperatures of less than 220° C. The obtained crosslinked silazane based polymer materials are of very high purity and do not show any discoloration or material deterioration when exposed to heat. They are therefore particularly suitable as technical coatings for applications where a homogeneous and uniform material texture, optical transparency and/or light fastness are important, such as e.g. encapsulation materials in optoelectronic devices including light emitting diodes (LEDs) and organic light emitting diodes (OLEDs). The method of the present invention allows a fast and efficient preparation of optoelectronic devices containing the crosslinked polymer material as encapsulation material. The present invention further relates to optoelectronic devices which are obtainable by said method. The optoelectronic devices show improved barrier properties, optical transparency, adjustable refractive index, mechanical stability (non-stickiness) and thermal and UV stability. Beyond that, a specific crosslinkable polymer formulation is provided which comprises a siloxazane polymer and a Lewis acid curing catalyst. Said crosslinkable polymer formulation is particularly suitable for the preparation of technical coatings on articles for industrial applications where a homogeneous and uniform material texture, optical transparency and/or light fastness are important features. Moreover, the present invention relates to a method for preparing such articles with technical coatings based on crosslinked siloxazane polymers and to articles which are by said method. The technical coatings may be protective surface coatings such as e.g. encapsulation or sealing coatings or functional coatings which impart special effects to surfaces such as e.g. anti-graffiti, scratch resistance, mechanical resistance, chemical resistance, hydro- and oleophobicity, hardness, light and temperature fastness, optical effects, antimicrobial, (non)conductive, (non)magnetic and corrosion resistance.

### BACKGROUND OF THE INVENTION

Polymers which contain a silazane repeating unit are typically referred to as polysilazanes or polysiloxazanes. While polysilazanes are composed of one or more different silazane repeating units, polysiloxazanes additionally contain one or more different siloxane repeating units. Polysilazanes and polysiloxazanes are usually liquid polymers which become solid at molecular weights of ca.>10.000 g/mol. In most applications liquid polymers of moderate molecular weights, typically in the range from 2.000 to 8.000 g/mol, are used. For preparing a solid coating from such liquid polymers, a curing step is required which is usually carried out at elevated temperatures after applying the material on a substrate, either as a pure material or as a formulation. Polysilazanes or polysiloxazanes are crosslinked by a hydrolysis reaction, wherein moisture from the air reacts according to the mechanisms as shown by Equations (I) and (II) below:

Hydrolysis of Si—N bond R₃Si—NH—SiR₃+H₂O—R₃Si—O—SiR₃+NH₃ Equation (I):

Hydrolysis of Si—H bond R₃Si-H+H-SiR₃+H₂O—R₃Si—O—SiR₃+2H₂ Equation (II):

During the hydrolysis reactions the polymers crosslink and the increasing molecular weight leads to a solidification of the material. Hence, the crosslinking reactions lead to a curing of the polysilazane or polysiloxazane material. For this reason, in the present application the terms “curing” and “crosslinking” and the corresponding verbs “cure” and “crosslink” are interchangeably used as synonyms when referred to silazane based polymers such as e.g. polysilazanes and polysiloxazanes.

Usually, curing is performed by hydrolysis at ambient conditions or at elevated temperatures of up to 220° C. or more. If possible, however, the curing time should be as low as possible.

Various catalysts have been described in the state of the art to catalyze the crosslinking process of polysilazanes under thermal conditions: WO 2007/028511 A2 relates to the use of polysilazanes as permanent coating on metal and polymer surfaces for preventing corrosion, increasing scratch resistance and to facilitate easier cleaning. Catalysts such as e.g. organic amines, organic acids, metals and metal salts may be used for curing the polysilazane formulation to obtain a permanent coating. Depending on the polysilazane formulation used and catalyst, curing takes place even at room temperature, but can be accelerated by heating.

Similarly, N-heterocyclic compounds, organic or inorganic acids, metal carboxylates, fine metal particles, peroxides, metal chlorides or organometallic compounds are suggested in WO 2004/039904 A1 for curing a polysilazane formulation under thermal conditions.

The coatings produced with the aforementioned methods require a relatively long curing time. Owing to the low film thickness, void formation is quite high and the barrier action of the coatings is unsatisfactory. Hence, there is a strong need to accelerate the crosslinking of polymers containing silazane repeating units, such as e.g. polysilazanes and polysiloxazanes, especially at ambient conditions, and to improve the material properties of the crosslinked polymer coatings.

Depending on the type of application, it is sometimes possible to use higher temperatures for curing, such as e.g. 220° C. or above. However, there are applications which do not tolerate high temperatures, or it is simply not possible to apply heat. Examples of such applications are the coating of railcars or subway trains or the coating of building facades in order to apply a protective layer against dirt and graffiti. In addition, elevated temperatures may be excluded due to the nature of the substrate to be coated. For example, most plastics start to degrade and decompose at temperatures of above 100° C. Until now, however, the curing of pure liquid polysilazanes or polysiloxazanes at ambient conditions is a rather slow process. Depending on the chemical composition, it might take several days to completely crosslink a polysilazane or polysiloxazane based coating.

In order to address this problem, various methods have been developed in which the curing takes place with the aid of VUV and/or UV radiation. For example, WO 2007/012392 A2 describes a method for producing a glassy, transparent coating on a substrate by (i) coating the substrate with a solution containing a polysilazane and a nitrogen-based basic catalyst in an organic solvent, (ii) removing the solvent using evaporation such that a polysilazane layer having a layer thickness of 0.05-3.0 μm remains on the substrate, and (iii) irradiating the polysilazane layer with VUV and UV radiation in an atmosphere containing steam and oxygen.

However, when using VUV radiation with wavelengths of <200 nm for curing, a nitrogen atmosphere is needed to avoid unfavorable absorption by oxygen taking place, for example, when using a Xenon Excimer Laser emitting at 172 nm. Likewise, when using UV radiation with wavelengths of <300 nm for curing, energy is lost by absorption of the polymer which results in the penetration depth being only some 100 nm which is not sufficient. When using UV radiation with wavelengths of >300 nm in a range where the polymer does not absorb, an UV active catalyst is required to promote a reaction between the reactive groups of the polymer, such as e.g. a UV radical starter initiating the Si—H/Si—CH═CH₂ addition.

It is well known in the art to use amine bases as catalysts for the crosslinking of polysilazanes under thermal conditions or under VUV and/or UV irradiation. Amine bases convert H₂O (which is present as moisture) into OH⁻ which attacks the silicon atom much faster than H₂O does. However, at higher temperatures (>200° C.) amines tend to get yellow and are therefore not suitable for applications where optical clarity of the crosslinked polymer composition is needed such as e.g. in optoelectronic devices like LEDs or OLEDs.

### Technical Problem and Object of the Invention

Various amine bases for the curing of silazane containing polymers have been proposed in the state of the art so far. However, there is a continuing need to accelerate the curing of silazane based polymers such as e.g. polysilazanes and polysiloxazanes and to enable an efficient crosslinking at moderate temperatures of preferably less than 220° C. This would allow a resource-saving and sustainable preparation of optoelectronic devices and articles which contain such crosslinked polymer materials as encapsulation materials or technical coatings. Hence, it is an object of the present invention to provide a method for preparing optoelectronic devices having a crosslinked polymer material as encapsulation material which does not suffer from discoloration or material deterioration when exposed to heat. The method should overcome the disadvantages in the state of the art and allow a fast and efficient production of optoelectronic devices. It is a further object of the present invention to provide optoelectronic devices which are obtainable by said method. Moreover, it is an object of the present invention to find a new crosslinkable polymer formulation which overcomes the disadvantages in the state of the art and allows a fast and efficient preparation of technical coatings on articles for industrial applications where a homogeneous and uniform material texture, optical transparency and/or light fastness play an important role. The crosslinkable polymer formulation should give crosslinked polymer materials that do not suffer from discoloration and material deterioration when exposed to heat and are therefore particularly suitable as technical coatings. Finally, it is an object of the present invention to provide a method for preparing such articles with technical coatings and to provide articles which are obtainable by said method.

### SUMMARY OF THE INVENTION

The present inventors have surprisingly found that the above objects can be solved either individually or in any combination by the embodiments as provided in the claims below.

The present inventors have found that specific Lewis acid compounds may be used as highly efficient catalysts for the curing of polymers containing silazane repeating units such as polysilazanes and/or polysiloxazanes. It is assumed that the Lewis acid catalysts activate the Si—N bonds which are contained in the polymer's backbone.

Hence, there is provided a method for preparing an optoelectronic device comprising a crosslinked polymer material which is prepared from a crosslinkable polymer formulation, wherein the method comprises the following steps: (a) applying a crosslinkable polymer formulation to a precursor of an optoelectronic device; and (b) curing said crosslinkable polymer formulation; characterized in that the crosslinkable polymer formulation comprises a polymer which contains a silazane repeating unit M¹, and a Lewis acid curing catalyst.

In addition, an optoelectronic device is provided which is obtainable by the above method.

Furthermore, a crosslinkable polymer formulation is provided which comprises a polymer, and a Lewis acid curing catalyst; characterized in that the polymer is a polysiloxazane which contains a repeating unit M¹ and a repeating unit M², wherein the repeating unit M¹ is represented by formula (I) and the repeating unit M² is represented by formula (III):

-[—SiR¹R²—NR³—]- (I)

-[—SiR⁷R⁸—[O—SiR⁷R⁸—]ₐ—NR⁹—]- (III)

wherein R¹, R², R³, R⁷, R⁸ and R⁹ are independently from each other selected from the group consisting of hydrogen, organyl and organoheteryl, and a is an integer from 1 to 60. The crosslinkable polymer formulation of the present invention is particularly suitable for the preparation of technical coatings such as protective surface coatings like encapsulation or sealing coatings for optoelectronic devices including LEDs and OLEDs or functional coatings which impart special effects to surfaces such as e.g. anti-graffiti, scratch resistance, mechanical resistance, chemical resistance, hydro- and oleophobicity, hardness, light and temperature fastness, optical effects, antimicrobial, (non)conductive, (non)magnetic and corrosion resistance. Hence, the crosslinkable polymer formulation may be used as encapsulation material for the preparation of converter layers of phosphor-converted LEDs (pc-LEDs) with high refractive index. The crosslinkable polymer formulation shows a higher curing rate when compared to conventional polymer formulations and thereby allows a more efficient processability. Moreover, the crosslinked polymer material does not show any discoloration or material deterioration when exposed to heat such as e.g. temperatures of >220° C.

In addition, a method for preparing an article comprising a crosslinked polymer material as technical coating is provided, wherein the technical coating is prepared from a crosslinkable polymer formulation according to the present invention and wherein the method comprises the following steps: (a) applying a crosslinkable polymer formulation of the present invention to a support; and curing said crosslinkable polymer formulation.

Finally, there is provided an article which is obtainable by the said method for preparing an article.

Preferred embodiments of the invention are described in the dependent claims.

### BRIEF DESCRIPTION OF THE FIGURES

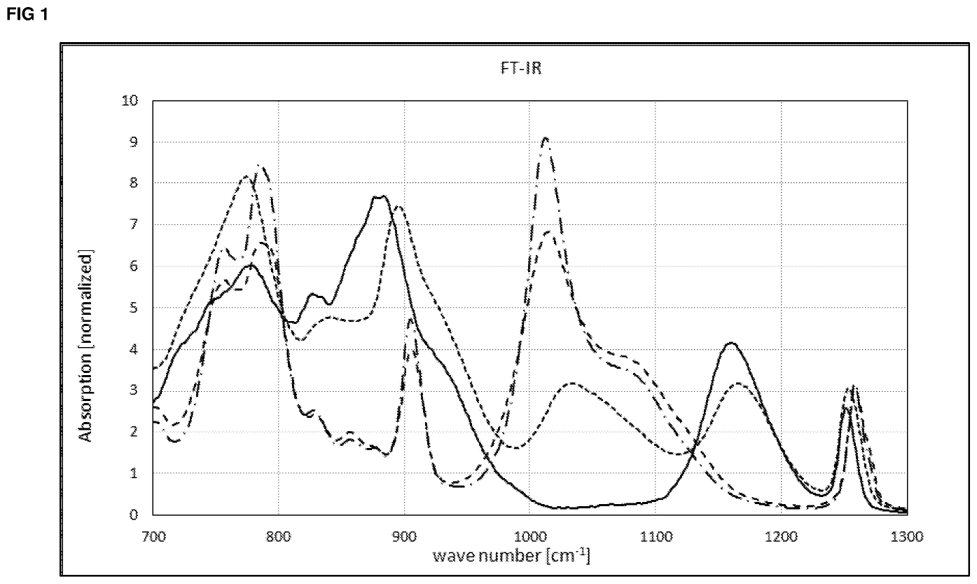

FIG. 1 shows FT-IR spectra of Example 1:
(1) [symbol] Durazane 1033, no heat treatment (raw material as reference)
(2) [symbol] Durazane 1033, no catalyst, 8 h at 150° C. and 8 h at 220° C.
(3) [symbol] Durazane 1033, triphenylaluminum, 8 h at 150° C.
(4) [symbol] Durazane 1033, triphenylaluminum, 8 h at 150° C. and 8 h at 220° C.

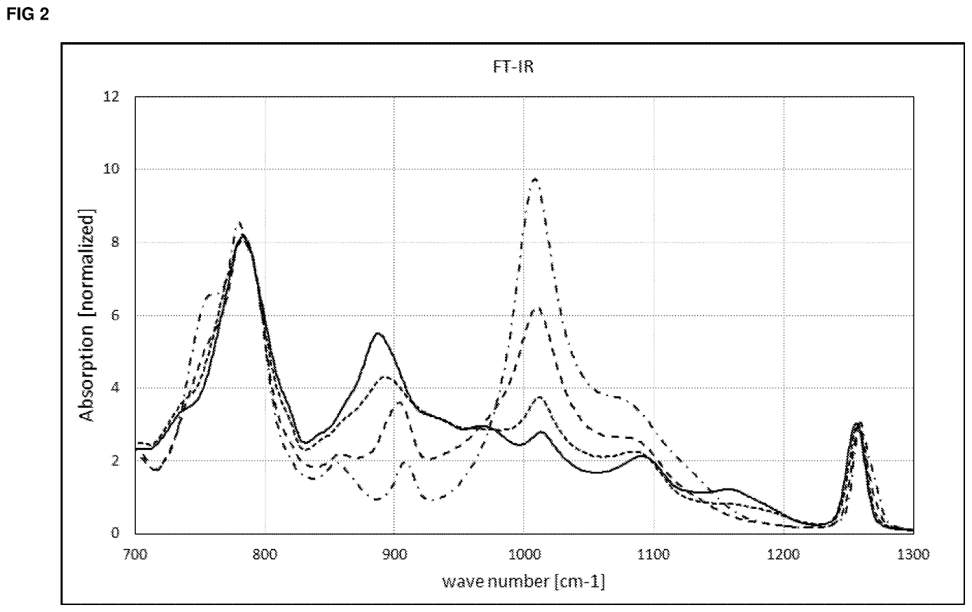

FIG. 2 shows FT-IR spectra of Example 5:
(1) [symbol] Material C, no heat treatment (raw material as reference)
(2) [symbol] Material C, no catalyst, 16 h at 150° C. and 8 h at 220° C.
(3) [symbol] Material C, catalyst 3, 16 h at 150° C.
(4) [symbol] Material C, catalyst 3, 16 h at 150° C. and 8 h at 220° C.

### DETAILED DESCRIPTION OF THE INVENTION

### Definitions

The term “crosslinkable polymer formulation” refers to a formulation comprising at least one crosslinkable polymer compound. A “crosslinkable polymer compound” is a polymer compound which may be crosslinked thermally, by the influence of radiation and/or a catalyst. A crosslinking reaction involves sites or groups on existing polymers or an interaction between existing polymers that results in the formation of a small region in a polymer from which at least three chains emanate. Said small region may be an atom, a group of atoms, or a number of branch points connected by bonds, groups of atoms or oligomeric or polymeric chains.

The term “polymer” includes, but is not limited to, homopolymers, copolymers, for example, block, random, and alternating copolymers, terpolymers, quaterpolymers, etc., and blends and modifications thereof. Furthermore, unless otherwise specifically limited, the term “polymer” shall include all possible configurational isomers of the material. These configurations include, but are not limited to isotactic, syndiotactic, and atactic symmetries. A polymer is a molecule of high relative molecular mass, the structure of which essentially comprises the multiple repetition of units (i.e. repeating units) derived, actually or conceptually, from molecules of low relative mass (i.e. monomers).

The term “monomer” as used herein refers to a molecule which can undergo polymerization thereby contributing constitutional units (repeating units) to the essential structure of a polymer.

The term “homopolymer” as used herein stands for a polymer derived from one species of (real, implicit or hypothetical) monomer.

The term “copolymer” as used herein generally means any polymer derived from more than one species of monomer, wherein the polymer contains more than one species of corresponding repeating unit. In one embodiment the copolymer is the reaction product of two or more species of monomer and thus comprises two or more species of corresponding repeating unit. It is preferred that the copolymer comprises two, three, four, five or six species of repeating unit. Copolymers that are obtained by copolymerization of three monomer species can also be referred to as terpolymers. Copolymers that are obtained by copolymerization of four monomer species can also be referred to as quaterpolymers. Copolymers may be present as block, random, and/or alternating copolymers.

The term “block copolymer” as used herein stands for a copolymer, wherein adjacent blocks are constitutionally different, i.e. adjacent blocks comprise repeating units derived from different species of monomer or from the same species of monomer but with a different composition or sequence distribution of repeating units.

Further, the term “random copolymer” as used herein refers to a polymer formed of macromolecules in which the probability of finding a given repeating unit at any given site in the chain is independent of the nature of the adjacent repeating units. Usually, in a random copolymer, the sequence distribution of repeating units follows Bernoullian statistics.

The term “alternating copolymer” as used herein stands for a copolymer consisting of macromolecules comprising two species of repeating units in alternating sequence.

The term “polysilazane” as used herein refers to a polymer in which silicon and nitrogen atoms alternate to form the basic backbone. Since each silicon atom is bound to at least one nitrogen atom and each nitrogen atom to at least one silicon atom, both chains and rings of the general formula [R¹R²Si—NR³]m occur, wherein R¹ to R³ can be hydrogen atoms or organic substituents; and m is an integer. If all substituents R¹ to R³ are H atoms, the polymer is designated as perhydropolysilazane, polyperhydrosilazane or inorganic polysilazane ([H₂Si—NH]ₘ). If at least one substituent R¹ to R³ is an organic substituent, the polymer is designated as organopolysilazane.

The term “polysiloxazane” as used herein refers to a polysilazane which additionally contains sections in which silicon and oxygen atoms alternate. Such section may be represented for example by [O—SiR⁴R⁵]ₙ, wherein R⁴ and R⁵ can be hydrogen atoms or organic substituents; and n is an integer. If all substituents of the polymer are H atoms, the polymer is designated as perhydropolysiloxazane. If at least one substituents of the polymer is an organic substituent, the polymer is designated as organopolysiloxazane.

The term “Lewis acid” as used herein means a molecular entity (and the corresponding chemical species) that is an electron-pair acceptor and therefore able to react with a Lewis base to form a Lewis adduct, by sharing the electron pair furnished by the Lewis base. A “Lewis base” as used herein is a molecular entity (and the corresponding chemical species) that is able to provide a pair of electrons and thus capable of coordination to a Lewis acid, thereby forming a Lewis adduct. A “Lewis adduct” is an adduct formed between a Lewis acid and a Lewis base.

The term “optoelectronic device” as used herein refers to electronic devices that operate on both light and electrical currents. This includes electrically driven light sources such as laser diodes, LEDs, OLEDs, OLETs (organic light emitting transistors) components for converting light to an electrical current such as solar and photovoltaic cells and devices that can electronically control the propagation of light.

The term “LED” as used herein refers to light emitting devices comprising one or more of a semiconductor light source (LED chip), lead frame, wiring, solder (flip chip), converter, filling material, encapsulation material, primary optics and/or secondary optics. An LED may be prepared from an LED precursor containing a semiconductor light source (LED chip) and/or lead frame and/or gold wire and/or solder (flip chip). In an LED precursor neither the LED chip nor the converter is enclosed by an encapsulation material. Usually, the encapsulation material and the converter form part of a converter layer. Such converter layer may be either arranged directly on an LED chip or alternatively arranged remote therefrom, depending on the respective type of application.

The term “OLED” as used herein refers to organic light emitting devices comprising electroactive organic light emitting materials generally, and includes but is not limited to organic light emitting diodes. An OLED device comprises at least two electrodes with an organic light-emitting material disposed between the two electrodes. Organic light-emitting materials are usually electroluminescent materials which emit light in response to the passage of an electric current or to a strong electric field.

The term “converter” as used herein means a material that converts light of a first wavelength to light of a second wavelength, wherein the second wavelength is different from the first wavelength. Converters are inorganic materials such as phosphors or quantum materials.

A “phosphor” is a fluorescent inorganic material which contains one or more light emitting centers. The light emitting centers are formed by activator elements such as e.g. atoms or ions of rare earth metal elements, for example La, Ce, Pr, Nd, Pm, Sm, Eu, Gd, Tb, Dy, Ho, Er, Tm, Yb and Lu, and/or atoms or ions of transition metal elements, for example Cr, Mn, Fe, Co, Ni, Cu, Ag, Au and Zn, and/or atoms or ions of main group metal elements, for example Na, TI, Sn, Pb, Sb and Bi. Examples of suitable phosphors include phosphors based on garnet, silicate, orthosilicate, thiogallate, sulfide, nitride, silicon-based oxynitride, nitridosilicate, nitridoaluminumsilicate, oxonitridosilicate, oxonitridoaluminumsilicate and rare earth doped sialon. Phosphors within the meaning of the present application are materials which absorb electromagnetic radiation of a specific wavelength range, preferably blue and/or ultraviolet (UV) electromagnetic radiation, and convert the absorbed electromagnetic radiation into electromagnetic radiation having a different wavelength range, preferably visible (VIS) light such as violet, blue, green, yellow, orange or red light.

A “quantum material” is a semiconductor nanocrystal forming a class of nanomaterials with physical properties that are widely tunable by controlling particle size, composition and shape. Among the most evident size dependent property of this class of materials is the tunable fluorescence emission. The tunability is afforded by the quantum confinement effect, where reducing particle size leads to a ‘particle in a box’ behavior, resulting in a blue shift of the band gap energy and hence the light emission. For example, in this manner, the emission of CdSe nanocrystals can be tuned from 660 nm for particles of diameter of 6.5 nm, to 500 nm for particles of diameter of 2 nm. Similar behavior can be achieved for other semiconductors when prepared as nanocrystals allowing for broad spectral coverage from the UV (using ZnSe, CdS for example) throughout the visible (using CdSe, InP for example) to the near-IR (using InAs for example). Changing the nanocrystal shape was demonstrated for several semiconductor systems, where especially prominent is the rod shape. Nanorods show properties that are modified from the spherical particles. For example, they exhibit emission that is polarized along the long rod axis, while spherical particles exhibit unpolarized emission. Moreover, we showed that nanorods have advantageous properties in optical gain, presenting potential for their use as laser materials (Banin et al., Adv. Mater., (2002) 14, 317). Single nanorods were also shown to exhibit a unique behavior under external electric fields—the emission can be switched on and off reversibly (Banin et. al., Nano Letters., (2005) 5, 1581).

The term “technical coating” as used herein refers to coatings in industrial and household areas including the electronic, optoelectronic and semiconductor industry. Technical coatings may be protective surface coatings including encapsulation or sealing coatings for integrated circuits (ICs) or optoelectronic devices such as e.g. LEDs and OLEDs. Technical coatings may also be functional coatings which impart special effects to surfaces as described below. Examples for “technical coatings” are in automobiles, construction or architectural areas. Generally, the coatings are needed to protect surfaces or impart special effects to surfaces. There are various effects which are imparted by organopolysil(ox)azane based coatings: e.g. anti-graffiti, scratch resistance, mechanical resistance, chemical resistance, hydro- and oleophobicity, hardness, light and temperature fastness, optical effects, antimicrobial, (non)conductive, (non)magnetic and corrosion resistance. A technical coating may comprise one or more layers.

The term “encapsulation material” or “encapsulant” as used herein means a material which covers or encloses a converter. Preferably, the encapsulation material forms part of a converter layer which contains one or more converters. The converter layer may be either arranged directly on a semiconductor light source (LED chip) or alternatively arranged remote therefrom, depending on the respective type of application. The converter layer may be present as a film having different thicknesses or having an uniform thickness. The encapsulation material forms a barrier against the external environment of the LED device, thereby protecting the converter and/or the LED chip. The encapsulating material is preferably in direct contact with the converter and/or the LED chip. Usually, the encapsulation material forms part of an LED package comprising an LED chip and/or lead frame and/or gold wire, and/or solder (flip chip), the filling material, converter and a primary and secondary optic. The encapsulation material may cover an LED chip and/or lead frame and/or gold wire and may contain a converter. The encapsulation material has the function of a surface protection material against external environmental influences and guarantees long term reliability that means aging stability. Preferably, the converter layer containing the encapsulation material has a thickness of 1 μm to 1 cm, more preferably of 10 μm to 1 mm.

The external environmental influences against which the encapsulation material needs to protect the LED may be chemical such as e.g. moisture, acids, bases, oxygen within others, or physical such as e.g. temperature, mechanical impact, or stress. The encapsulation material can act as a binder for the converter, such as a phosphor powder or a quantum material (e.g. quantum dots). The encapsulant can also be shaped in order to provide primary optic functions (lens).

It is noted that the terms “layer” and “layers” are used interchangeably throughout the application. A person of ordinary skill in the art will understand that a single “layer” of material may actually comprise several individual sub-layers of material. Likewise, several “sub-layers” of material may be considered functionally as a single layer. In other words the term “layer” does not denote a homogenous layer of material. A single “layer” may contain various material concentrations and compositions that are localized in sub-layers. These sub-layers may be formed in a single formation step or in multiple steps. Unless specifically stated otherwise, it is not intended to limit the scope of the invention as embodied in the claims by describing an element as comprising a “layer” or “layers” of material.

For the purposes of the present application the term “organyl” is used to denote any organic substituent group, regardless of functional type, having one free valence at a carbon atom.

For the purposes of the present application the term “organoheteryl” is used to denote any univalent group containing carbon, which is thus organic, but which has the free valence at an atom other than carbon being a heteroatom.

As used herein, the term “heteroatom” will be understood to mean an atom in an organic compound that is not a H- or C-atom, and preferably will be understood to mean N, O, S, P, Si, Se, As, Te or Ge.

An organyl or organoheteryl group comprising a chain of 3 or more C atoms may be straight-chain, branched-chain and/or cyclic, including spiro and/or fused rings.

Preferred organyl and organoheteryl groups include alkyl, alkoxy, alkylsilyl, alkylsilyloxy, alkylcarbonyl, alkoxycarbonyl, alkylcarbonyloxy and alkoxycarbonyloxy, each of which is optionally substituted and has 1 to 40, preferably 1 to 25, more preferably 1 to 18 C atoms, furthermore optionally substituted aryl, aryloxy, arylsilyl or arylsilyloxy having 6 to 40, preferably 6 to 25 C atoms, furthermore alkylaryloxy, alkylarylsilyl, alkylarylsilyloxy, arylalkylsilyl, arylalkylsilyloxy, arylcarbonyl, aryloxycarbonyl, arylcarbonyloxy and aryloxycarbonyloxy, each of which is optionally substituted and has 7 to 40, preferably 7 to 20 C atoms, wherein all these groups do optionally contain one or more heteroatoms, preferably selected from N, O, S, P, Si, Se, As, Te and Ge.

The organyl or organoheteryl group may be a saturated or unsaturated acyclic group, or a saturated or unsaturated cyclic group. Unsaturated acyclic or cyclic groups are preferred, especially aryl, alkenyl and alkynyl groups (especially ethynyl). Where the C₁-C₄₀ organyl or organoheteryl group is acyclic, the group may be straight-chain or branched-chain. The C₁-C₄₀ organyl or organoheteryl group includes for example: a C₁-C₄₀ alkyl group, a C₁-C₄₀ fluoroalkyl group, a C₁-C₄₀ alkoxy or oxaalkyl group, a C₂-C₄₀ alkenyl group, a C₂-C₄₀ alkynyl group, a C₃-C₄₀ allyl group, a C₄-C₄₀ alkyldienyl group, a C₄-C₄₀ polyenyl group, a C₂-C₄₀ ketone group, a C₂-C₄₀ ester group, a C₆-C₁₈ aryl group, a C₆-C₄₀ alkylaryl group, a C₆-C₄₀ arylalkyl group, a C₄-C₄₀ cycloalkyl group, a C₄-C₄₀ cycloalkenyl group, and the like. Preferred among the foregoing groups are a C₁-C₂₀ alkyl group, a C₁-C₂₀ fluoroalkyl group, a C₂-C₂₀ alkenyl group, a C₂-C₂₀ alkynyl group, a C₃-C₂₀ allyl group, a C₄-C₂₀ alkyldienyl group, a C₂-C₂₀ ketone group, a C₂-C₂₀ ester group, a C₆-C₁₂ aryl group, and a C₄-C₂₀ polyenyl group, respectively. Also included are combinations of groups having carbon atoms and groups having heteroatoms, such as e.g. an alkynyl group, preferably ethynyl, that is substituted with a silyl group, preferably a trialkylsilyl group.

The terms “aryl” and “heteroaryl” as used herein preferably mean a mono-, bi- or tricyclic aromatic or heteroaromatic group with 4 to 18 ring C atoms that may also comprise condensed rings and is optionally substituted with one or more groups L, wherein L is selected from halogen, —CN, —NC, —NCO, —NCS, —OCN, —SCN, —C(═O)NR⁰R⁰⁰, —C(═O)X⁰, —C(═O)R, —NH₂, —NR⁰R⁰⁰, —SH, —SR, —SO₃H, —SO₂R, —OH, —NO₂, —CF₃, —SF₅, optionally substituted silyl, or organyl or organoheteryl with 1 to 40 C atoms that is optionally substituted and optionally comprises one or more heteroatoms, and is preferably alkyl, alkoxy, thiaalkyl, alkylcarbonyl, alkoxycarbonyl or alkoxycarbonyloxy with 1 to 20 C atoms that is optionally fluorinated, and R⁰, R⁰⁰ and X⁰ have the meanings as given below.

Very preferred substituents L are selected from halogen, most preferably F, or alkyl, alkoxy, oxaalkyl, thioalkyl, fluoroalkyl and fluoroalkoxy with 1 to 12 C atoms or alkenyl, and alkynyl with 2 to 12 C atoms.

Especially preferred aryl and heteroaryl groups are phenyl, pentafluorophenyl, phenyl wherein one or more CH groups are replaced by N, naphthalene, thiophene, selenophene, thienothiophene, dithienothiophene, fluorene and oxazole, all of which can be unsubstituted, mono- or polysubstituted with L as defined above. Very preferred rings are selected from pyrrole, preferably N-pyrrole, furan, pyridine, preferably 2- or 3-pyridine, pyrimidine, pyridazine, pyrazine, triazole, tetrazole, pyrazole, imidazole, isothiazole, thiazole, thiadiazole, isoxazole, oxazole, oxadiazole, thiophene, preferably 2-thiophene, selenophene, preferably 2-selenophene, thieno[3,2-b]thiophene, thieno[2,3-b]thiophene, furo[3,2-b]furan, furo[2,3-b]furan, seleno[3,2-b]selenophene, seleno[2,3-b]selenophene, thieno[3,2-b]selenophene, thieno[3,2-b]furan, indole, isoindole, benzo[b]furan, benzo[b]thiophene, benzo[1,2-b;4,5-b′]dithiophene, benzo[2,1-b;3,4-b′]dithiophene, quinole, 2-methylquinole, isoquinole, quinoxaline, quinazoline, benzotriazole, benzimidazole, benzothiazole, benzisothiazole, benzisoxazole, benzoxadiazole, benzoxazole, benzothiadiazole, all of which can be unsubstituted, mono- or polysubstituted with L as defined above. Further examples of aryl and heteroaryl groups are those selected from the groups shown hereinafter.

An alkyl or alkoxy radical, i.e. where the terminal CH₂ group is replaced by —O—, can be straight-chain or branched-chain. It is preferably straight-chain (or linear). Suitable examples of such alkyl and alkoxy radical are methyl, ethyl, propyl, butyl, pentyl, hexyl, heptyl, octyl, nonyl, decyl, undecyl, dodecyl, tridecyl, tetradecyl, pentadecyl, methoxy, ethoxy, propoxy, butoxy, pentoxy, hexoxy, heptoxy, octoxy, nonoxy, decoxy, undecoxy, dodecoxy, tridecoxy or tetradecoxy. Preferred alkyl and alkoxy radicals have 1, 2, 3, 4, 5, 6, 7, 8, 9 or 10 carbon atoms. Suitable examples of such preferred alkyl and alkoxy radicals may be selected from the group consisting of methyl, ethyl, propyl, butyl, pentyl, hexyl, heptyl, octyl, nonyl, decyl, methoxy, ethoxy, propoxy, butoxy, pentoxy, hexoxy, heptoxy, octoxy, nonoxy and decoxy.

An alkenyl group, wherein one or more CH₂ groups are replaced by —CH═CH— can be straight-chain or branched-chain. It is preferably straight-chain, has 2 to 10 C atoms and accordingly is preferably vinyl, prop-1-enyl, or prop-2-enyl, but-1-enyl, but-2-enyl or but-3-enyl, pent-1-enyl, pent-2-enyl, pent-3-enyl or pent-4-enyl, hex-1-enyl, hex-2-enyl, hex-3-enyl, hex-4-enyl or hex-5-enyl, hept-1-enyl, hept-2-enyl, hept-3-enyl, hept-4-enyl, hept-5-enyl or hept-6-enyl, oct-1-enyl, oct-2-enyl, oct-3-enyl, oct-4-enyl, oct-5-enyl, oct-6-enyl or oct-7-enyl, non-1-enyl, non-2-enyl, non-3-enyl, non-4-enyl, non-5-enyl, non-6-enyl, non-7-enyl or non-8-enyl, dec-1-enyl, dec-2-enyl, dec-3-enyl, dec-4-enyl, dec-5-enyl, dec-6-enyl, dec-7-enyl, dec-8-enyl or dec-9-enyl.

Especially preferred alkenyl groups are C₂-C₇-1E-alkenyl, C₄-C₇-3E-alkenyl, C₅-C₇-4-alkenyl, C₆-C₇-5-alkenyl and C₇-6-alkenyl, in particular C₂-C₇-1E-alkenyl, C₄-C₇-3E-alkenyl and C₅-C₇-4-alkenyl. Examples for particularly preferred alkenyl groups are vinyl, 1E-propenyl, 1E-butenyl, 1E-pentenyl, 1E-hexenyl, 1E-heptenyl, 3-butenyl, 3E-pentenyl, 3E-hexenyl, 3E-heptenyl, 4-pentenyl, 4Z-hexenyl, 4E-hexenyl, 4Z-heptenyl, 5-hexenyl, 6-heptenyl and the like. Alkenyl groups having up to 5 C atoms are generally preferred.

An oxaalkyl group, i.e. where one CH₂ group is replaced by —O—, is preferably straight-chain 2-oxapropyl (=methoxymethyl), 2-(ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example. Oxaalkyl, i.e. where one CH₂ group is replaced by —O—, is preferably straight-chain 2-oxapropyl (=methoxymethyl), 2- (=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example.

In an alkyl group wherein one CH₂ group is replaced by —O— and one by —C(O)—, these radicals are preferably neighbored. Accordingly these radicals together form a carbonyloxy group —C(O)—O— or an oxycarbonyl group —O—C(O)—. Preferably this group is straight-chain and has 2 to 6 C atoms. It is accordingly preferably selected from the group consisting of acetyloxy, propionyloxy, butyryloxy, pentanoyloxy, hexanoyloxy, acetyloxymethyl, propionyloxymethyl, butyryloxymethyl, pentanoyloxymethyl, 2-acetyloxyethyl, 2-propionyloxyethyl, 2-butyryloxyethyl, 3-acetyloxypropyl, 3-propionyloxypropyl, 4-acetyloxybutyl, methoxycarbonyl, ethoxycarbonyl, propoxycarbonyl, butoxycarbonyl, pentoxycarbonyl, methoxycarbonylmethyl, ethoxycarbonylmethyl, propoxycarbonylmethyl, butoxycarbonylmethyl, 2-(methoxycarbonyl)ethyl, 2-(ethoxycarbonyl)ethyl, 2-(propoxycarbonyl)ethyl, 3-(methoxycarbonyl)propyl, 3-(ethoxycarbonyl)propyl, and 4-(methoxycarbonyl)-butyl.

An alkyl group wherein two or more CH₂ groups are replaced by —O— and/or —C(O)O— can be straight-chain or branched-chain. It is preferably straight-chain and has 3 to 12 C atoms. Accordingly it is preferably selected from the group consisting of bis-carboxy-methyl, 2,2-bis-carboxy-ethyl, 3,3-bis-carboxy-propyl, 4,4-bis-carboxy-butyl, 5,5-bis-carboxy-pentyl, 6,6-bis-carboxy-hexyl, 7,7-bis-carboxy-heptyl, 8,8-bis-carboxy-octyl, 9,9-bis-carboxy-nonyl, 10,10-bis-carboxy-decyl, bis-(methoxycarbonyl)-methyl, 2,2-bis-(methoxycarbonyl)-ethyl, 3,3-bis-(methoxycarbonyl)-propyl, 4,4-bis-(methoxycarbonyl)-butyl, 5,5-bis-(methoxycarbonyl)-pentyl, 6,6-bis-(methoxycarbonyl)-hexyl, 7,7-bis-(methoxycarbonyl)-heptyl, 8,8-bis-(methoxycarbonyl)-octyl, bis-(ethoxycarbonyl)-methyl, 2,2-bis-(ethoxycarbonyl)-ethyl, 3,3-bis-(ethoxycarbonyl)-propyl, 4,4-bis-(ethoxycarbonyl)-butyl, and 5,5-bis-(ethoxycarbonyl)-hexyl.

A thioalkyl group, i.e. where one CH₂ group is replaced by —S—, is preferably straight-chain thiomethyl (—SCH₃), 1-thioethyl (—SCH₂CH₃), 1-thiopropyl (=—SCH₂CH₂CH₃), 1-(thiobutyl), 1-(thiopentyl), 1-(thiohexyl), 1-(thioheptyl), 1-(thiooctyl), 1-(thiononyl), 1-(thiodecyl), 1-(thioundecyl) or 1-(thiododecyl), wherein preferably the CH₂ group adjacent to the sp² hybridised vinyl carbon atom is replaced.

A fluoroalkyl group is preferably perfluoroalkyl, CᵢF₂ᵢ₊₁, wherein i is an integer from 1 to 15, in particular CF₃, C₂F₅, C₃F₇, C₄F₉, C₅F₁₁, C₆F₁₃, C₇F₁₅ or C₈F₁₇, very preferably C₆F₁₃, or partially fluorinated alkyl, in particular 1,1-difluoroalkyl, all of which are straight-chain or branched-chain.

Alkyl, alkoxy, alkenyl, oxaalkyl, thioalkyl, carbonyl and carbonyloxy groups can be achiral or chiral groups. Particularly preferred chiral groups are 2-butyl (=1-methylpropyl), 2-methylbutyl, 2-methylpentyl, 3-methylpentyl, 2-ethylhexyl, 2-propylpentyl, in particular 2-methylbutyl, 2-methylbutoxy, 2-methylpentoxy, 3-methylpentoxy, 2-ethyl-hexoxy, 1-methylhexoxy, 2-octyloxy, 2-oxa-3-methylbutyl, 3-oxa-4-methyl-pentyl, 4-methylhexyl, 2-hexyl, 2-octyl, 2-nonyl, 2-decyl, 2-dodecyl, 6-meth-oxyoctoxy, 6-methyloctoxy, 6-methyloctanoyloxy, 5-methylheptyloxy-carbonyl, 2-methylbutyryloxy, 3-methylvaleroyloxy, 4-methylhexanoyloxy, 2-chloropropionyloxy, 2-chloro-3-methylbutyryloxy, 2-chloro-4-methyl-valeryl-oxy, 2-chloro-3-methylvaleryloxy, 2-methyl-3-oxapentyl, 2-methyl-3-oxa-hexyl, 1-methoxypropyl-2-oxy, 1-ethoxypropyl-2-oxy, 1-propoxypropyl-2-oxy, 1-butoxypropyl-2-oxy, 2-fluorooctyloxy, 2-fluorodecyloxy, 1,1,1-trifluoro-2-octyloxy, 1,1,1-trifluoro-2-octyl, 2-fluoromethyloctyloxy for example. Very preferred are 2-hexyl, 2-octyl, 2-octyloxy, 1,1,1-trifluoro-2-hexyl, 1,1,1-trifluoro-2-octyl and 1,1,1-trifluoro-2-octyloxy.

Preferred achiral branched groups are isopropyl, isobutyl (=methylpropyl), isopentyl (=3-methylbutyl), tert. butyl, isopropoxy, 2-methyl-propoxy and 3-methylbutoxy.

In a preferred embodiment, the organyl and organoheteryl groups are independently of each other selected from primary, secondary or tertiary alkyl or alkoxy with 1 to 30 C atoms, wherein one or more H atoms are optionally replaced by F, or aryl, aryloxy, heteroaryl or heteroaryloxy that is optionally alkylated or alkoxylated and has 4 to 30 ring atoms. Very preferred groups of this type are selected from the group consisting of the following formulae

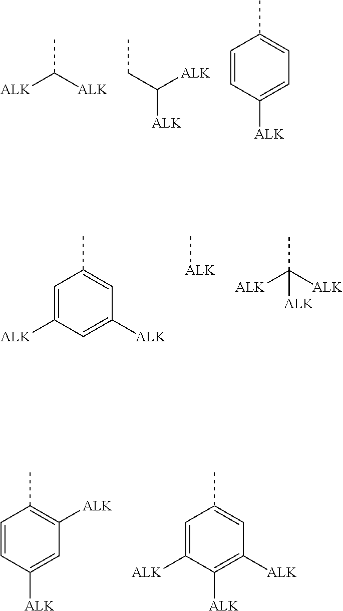

wherein “ALK” denotes optionally fluorinated, preferably linear, alkyl or alkoxy with 1 to 20, preferably 1 to 12 C-atoms, in case of tertiary groups very preferably 1 to 9 C atoms, and the dashed line denotes the link to the ring to which these groups are attached. Especially preferred among these groups are those wherein all ALK subgroups are identical.

As used herein, “halogen” includes F, Cl, Br or I, preferably F, Cl or Br, more preferably F and Cl, and most preferably F.

For the purposes of the present application the term “substituted” is used to denote that one or more hydrogen present is replaced by a group R^{S} as defined herein.

R^{S} is at each occurrence independently selected from the group consisting of any group R^{T} as defined herein, organyl or organoheteryl having from 1 to 40 carbon atoms wherein the organyl or organoheteryl may be further substituted with one or more groups R^{T} and organyl or organoheteryl having from 1 to 40 carbon atoms comprising one or more heteroatoms selected from the group consisting of N, O, S, P, Si, Se, As, Te, Ge, F and Cl, with N, O and S being preferred heteroatoms, wherein the organyl or organoheteryl may be further substituted with one or more groups R^{T}.

Preferred examples of organyl or organoheteryl suitable as R^{S} may at each occurrence be independently selected from phenyl, phenyl substituted with one or more groups R^{T}, alkyl and alkyl substituted with one or more groups R^{T}, wherein the alkyl has at least 1, preferably at least 5, more preferably at least 10 and most preferably at least 15 carbon atoms and/or has at most 40, more preferably at most 30, even more preferably at most 25 and most preferably at most 20 carbon atoms. It is noted that for example alkyl suitable as R^{S} also includes fluorinated alkyl, i.e. alkyl wherein one or more hydrogen is replaced by fluorine, and perfluorinated alkyl, i.e. alkyl wherein all of the hydrogen are replaced by fluorine.

R^{T} is at each occurrence independently selected from the group consisting of F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —OR⁰, —NO₂, —SF₅ and —SiR⁰R⁰⁰R⁰⁰⁰. Preferred R^{T} are selected from the group consisting of F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR, —OH, —OR⁰ and —SiR⁰R⁰⁰R⁰⁰⁰.

R⁰, R⁰⁰ and R⁰⁰⁰ are at each occurrence independently of each other selected from the group consisting of H, F, organyl or organoheteryl having from 1 to 40 carbon atoms. Said organyl or organoheteryl preferably have at least 5, more preferably at least 10 and most preferably at least 15 carbon atoms. Said organyl or organoheteryl preferably have at most 30, even more preferably at most 25 and most preferably at most 20 carbon atoms. Preferably, R⁰, R⁰⁰ and R⁰⁰⁰ are at each occurrence independently of each other selected from the group consisting of H, F, alkyl, fluorinated alkyl, alkenyl, alkynyl, phenyl and fluorinated phenyl. More preferably, R⁰, R⁰⁰ and R⁰⁰⁰ are at each occurrence independently of each other selected from the group consisting of H, F, alkyl, fluorinated, preferably perfluorinated, alkyl, phenyl and fluorinated, preferably perfluorinated, phenyl.

It is noted that for example alkyl suitable as R⁰, R⁰⁰ and R⁰⁰⁰ also includes perfluorinated alkyl, i.e. alkyl wherein all of the hydrogen are replaced by fluorine. Examples of alkyls may be selected from the group consisting of methyl, ethyl, n-propyl, iso-propyl, n-butyl, iso-butyl, tert-butyl (or “t-butyl”), pentyl, hexyl, heptyl, octyl, nonyl, decyl, undecyl, dodecyl, tridecyl, tetradecyl, pentadecyl, hexadecyl, heptadecyl, octadecyl, nonadecyl and eicosyl (—C₂₀H₄₁).

X⁰ is a halogen. Preferably X⁰ is selected from the group consisting of F, Cl and Br.

The present invention relates to a method for preparing an optoelectronic device comprising a crosslinked polymer material which is prepared from a crosslinkable polymer formulation, wherein the method comprises the following steps: (a) applying a crosslinkable polymer formulation to a precursor of an optoelectronic device; and (b) curing said crosslinkable polymer formulation; characterized in that the crosslinkable polymer formulation comprises a polymer containing a silazane repeating unit M¹, and a Lewis acid curing catalyst.

Preferably, the polymer contains a repeating unit M¹ and a further repeating unit M², wherein M¹ and M² are silazane units which are different from each other. Preferably, the polymer contains a repeating unit M¹ and a further repeating unit M³, wherein M¹ is a silazane unit and M³ is a siloxazane unit. More preferably, the polymer contains a repeating unit M¹, a further repeating unit M² and a further repeating unit M³, wherein M¹ and M² are silazane units which are different from each other and M³ is a siloxazane unit.

In a preferred embodiment the polymer is a polysilazane which may be a perhydropolysilazane or an organopolysilazane. Preferably, the polysilazane contains a repeating unit M¹ and optionally a further repeating unit M², wherein M¹ and M² are silazane units which are different from each other.

In an alternative preferred embodiment the polymer is a polysiloxazane which may be a perhydropolysiloxazane or an organopolysiloxazane. Preferably, the polysiloxazane contains a repeating unit M¹ and a further repeating unit M³, wherein M¹ is a silazane unit and M³ is a siloxazane unit. More preferably, the polysiloxazane contains a repeating unit M¹, a further repeating unit M² and a further repeating unit M³, wherein M¹ and M² are silazane units which are different from each other and M³ is a siloxazane unit.

In a particularly preferred embodiment the polymer is a mixture of a polysilazane which may be a perhydropolysilazane or an organopolysilazane and a polysiloxazane which may be a perhydropolysiloxazane or an organopolysiloxazane.

As noted above, one component of the crosslinkable polymer composition which is used in the method according to the present invention is a polymer containing a silazane repeating unit M¹. Preferably, the silazane repeating unit M¹ is represented by formula (I):

-[—SiR¹R²—NR³—]- (I)

wherein R¹, R² and R³ are independently from each other selected from the group consisting of hydrogen, organyl and organoheteryl.

It is preferred that R¹, R² and R³ in formula (I) are independently from each other selected from the group consisting of hydrogen, alkyl having 1 to 40 carbon atoms, alkenyl having 2 to 40 carbon atoms and aryl having from 6 to 30 carbon atoms. More preferably, R¹, R² and R³ are independently from each other selected from the group consisting of hydrogen, alkyl having 1 to 20 carbon atoms, alkenyl having 2 to 20 carbon atoms and phenyl. Most preferably, R¹, R² and R³ are independently from each other hydrogen, methyl or vinyl.

In a preferred embodiment, the polymer contains besides the silazane repeating unit M¹ a further repeating unit M² which is represented by formula (II):

-[—SiR⁴R⁵—NR⁶—]- (II)

wherein R⁴, R⁵ and R⁶ are at each occurrence independently from each other selected from the group consisting of hydrogen, organyl and organoheteryl; and wherein M² is different from M¹.

It is preferred that R⁴, R⁵ and R⁶ in formula (II) are independently from each other selected from the group consisting of hydrogen, alkyl having 1 to 40 carbon atoms, alkenyl having 2 to 40 carbon atoms and aryl having from 6 to 30 carbon atoms. More preferably, R⁴, R⁵ and R⁶ are independently from each other selected from the group consisting of hydrogen, alkyl having 1 to 20 carbon atoms, alkenyl having 2 to 20 carbon atoms and phenyl. Most preferably, R⁴, R⁵ and R⁶ are independently from each other hydrogen, methyl or vinyl.

In a further preferred embodiment, the polymer is a polysiloxazane which contains besides the silazane repeating unit M¹ a further repeating unit M³ which is represented by formula (III):

-[—SiR⁷R⁸—[O—SiR⁷R⁸—]ₐ—NR⁹—]- (III)

wherein R⁷, R⁸, R⁹ are independently from each other selected from the group consisting of hydrogen, organyl and organoheteryl; and a is an integer from 1 to 60, preferably from 1 to 50. More preferably, a may be an integer from 5 to 50 (long chain monomer M³); or a may be an integer from 1 to 4 (short chain monomer M³).

It is preferred that R⁷, R⁸ and R⁹ in formula (III) are independently from each other selected from the group consisting of hydrogen, alkyl having 1 to 40 carbon atoms, alkenyl having 2 to 40 carbon atoms and aryl having from 6 to 30 carbon atoms. More preferably, R⁷, R⁸ and R⁹ are independently from each other selected from the group consisting of hydrogen, alkyl having 1 to 20 carbon atoms, alkenyl having 2 to 20 carbon atoms and phenyl. Most preferably, R⁷, R⁸ and R⁹ are independently from each other hydrogen, methyl or vinyl.

With respect to R¹, R², R³, R⁴, R⁵, R⁶, R⁷, R⁸ and R⁹ preferred organyl groups may be independently selected from the group consisting of alkyl, substituted alkyl, cycloalkyl, substituted cycloalkyl, alkenyl, substituted alkenyl, alkadienyl, substituted alkadienyl, alkynyl, substituted alkynyl, aryl, and substituted aryl.

With respect to R¹, R², R³, R⁴, R⁵, R⁶, R⁷, R⁸ and R⁹ more preferred organyl groups be independently selected from the group consisting of alkyl, substituted alkyl, cycloalkyl, substituted cycloalkyl, alkenyl, substituted alkenyl, alkadienyl and substituted alkadienyl.

With respect to R¹, R², R³, R⁴, R⁵, R⁶, R⁷, R⁸ and R⁹ even more preferred organyl groups may be independently selected from the group consisting of alkyl, substituted alkyl, alkenyl, substituted alkenyl, alkadienyl and substituted alkadienyl.

With respect to R¹, R², R³, R⁴, R⁵, R⁶, R⁷, R⁸ and R⁹ still even more preferred organyl groups may be independently selected from the group consisting of alkyl and substituted alkyl.

With respect to R¹, R², R³, R⁴, R⁵, R⁶, R⁷, R⁸ and R⁹ most preferred organyl groups may be independently selected from alkyl.

With respect to R¹, R², R³, R⁴, R⁵, R⁶, R⁷, R⁸ and R⁹ preferred alkyl may be selected from alkyls having at least 1 carbon atom and at most 40 carbon atoms, preferably at most 30 or 20 carbon atoms, more preferably at most 15 carbon atoms, still even more preferably at most 10 carbon atoms and most preferably at most 5 carbon atoms.

With respect to R¹, R², R³, R⁴, R⁵, R⁶, R⁷, R⁸ and R⁹ alkyl having at least 1 carbon atom and at most 5 carbon atoms may be independently selected from the group consisting of methyl, ethyl, n-propyl, iso-propyl, n-butyl, iso-butyl, tert-butyl, n-pentyl, iso-pentyl (2,2-methyl-butyl) and neo-pentyl (2,2-dimethyl-propyl); preferably from the group consisting of methyl, ethyl, n-propyl and iso-propyl; more preferably from methyl or ethyl; and most preferably from methyl.

With respect to R¹, R², R³, R⁴, R⁵, R⁶, R⁷, R⁸ and R⁹ preferred cycloalkyl may be selected from cycloalkyl having at least 3, preferably at least 4 and most preferably at least 5 carbon atoms. Preferred cycloalkyl may be selected from cycloalkyl having at most 30, preferably at most 25, more preferably at most 20, even more preferably at most 15, and most preferably at most 10 carbon atoms.

With respect to R¹, R², R³, R⁴, R⁵, R⁶, R⁷, R⁸ and R⁹ preferred examples of cycloalkyl may be selected from the group consisting of cyclopentyl, cyclohexyl, cycloheptyl and cyclooctyl.

With respect to R¹, R², R³, R⁴, R⁵, R⁶, R⁷, R⁸ and R⁹ preferred alkenyl may be selected from alkenyl having at least 2 carbon atoms and at most 20, more preferably at most 15, even more preferably at most 10, and most preferably at most 6 carbon atoms. Said alkenyl may comprise the C═C double bond at any position within the molecule; for example, the C═C double bond may be terminal or non-terminal.

With respect to R¹, R², R³, R⁴, R⁵, R⁶, R⁷, R⁸ and R⁹ alkenyl having at least 2 and at most 10 carbon atoms may be vinyl or allyl, preferably vinyl.

With respect to R¹, R², R³, R⁴, R⁵, R⁶, R⁷, R⁸ and R⁹ preferred alkadienyl may be selected from alkadienyl having at least 4 and at most 20, more preferably at most 15, even more preferably at most 10, and most preferably at most 6 carbon atoms. Said alkenyl may comprise the two C═C double bonds at any position within the molecule, provided that the two C═C double bonds are not adjacent to each other; for example, the C═C double bonds may be terminal or non-terminal.

With respect to R¹, R², R³, R⁴, R⁵, R⁶, R⁷, R⁸ and R⁹ alkadienyl having at least 4 and at most 6 carbon atoms may, for example, be butadiene or hexadiene.

With respect to R¹, R², R³, R⁴, R⁵, R⁶, R⁷, R⁸ and R⁹ preferred aryl may be selected from aryl having at least 6 carbon atoms, and at most 30, preferably at most 24 carbon atoms.

With respect to R¹, R², R³, R⁴, R⁵, R⁶, R⁷, R⁸ and R⁹ preferred examples of aryl may be selected from the group consisting of phenyl, naphthyl, phenanthrenyl, anthracenyl, tetracenyl, benz[a]anthracenyl, pentacenyl, chrysenyl, benzo[a]pyrenyl, azulenyl, perylenyl, indenyl, fluorenyl and any of these wherein one or more (for example 2, 3 or 4) CH groups are replaced by N. Of these phenyl, naphthyl and any of these wherein one or more (for example 2, 3 or 4) CH groups are replaced by N. Phenyl is most preferred.

With respect to R¹, R², R³, R⁴, R⁵, R⁶, R⁷, R⁸ and R⁹ preferred organoheteryl groups may be independently selected from the group consisting of alkoxy, alkylsilyl, alkylsilyloxy, alkylcarbonyloxy and alkoxycarbonyloxy, each of which is optionally substituted and has 1 to 40, preferably 1 to 20, more preferably 1 to 18 C atoms; optionally substituted aryloxy, arylsilyl and arylsilyloxy each of which has 6 to 40, preferably 6 to 20 C atoms; and alkylaryloxy, alkylarylsilyl, alkylarylsilyloxy, arylalkylsilyl, arylalkylsilyloxy, arylcarbonyl, aryloxycarbonyl, arylcarbonyloxy and aryloxycarbonyloxy, each of which is optionally substituted and has 7 to 40, preferably 7 to 20 C atoms, wherein all these groups do optionally contain one or more heteroatoms, preferably selected from N, O, S, P, Si, Se, As, Te, Ge, F and Cl. The organoheteryl group may be a saturated or unsaturated acyclic group, or a saturated or unsaturated cyclic group. Unsaturated acyclic or cyclic groups are preferred. Where the organoheteryl group is acyclic, the group may be straight-chain or branched-chain.

With respect to R¹, R², R³, R⁴, R⁵, R⁶, R⁷, R⁸ and R⁹ further preferred organoheteryl groups may be selected from the organoheteryl groups as defined in the definitions above.

It is understood that the skilled person can freely combine the above-mentioned preferred and more preferred embodiments relating to the substituents R¹, R², R³, R⁴, R⁵, R⁶, R⁷, R⁸ and R⁹ in the polymer in any desired way.

Preferably, the polymer is a copolymer such as a random copolymer or a block copolymer or a copolymer containing at least one random sequence section and at least one block sequence section. More preferably, the polymer is a random copolymer or a block copolymer.

Preferably, the polymers used in the present invention have a molecular weight M_{w}, as determined by GPC, of at least 1,000 g/mol, more preferably of at least 2,000 g/mol, even more preferably of at least 3,000 g/mol. Preferably, the molecular weight M_{w} of the polymers is less than 100,000 g/mol. More preferably, the molecular weight M_{w} of the polymers is in the range from 3,000 to 50,000 g/mol.

Preferably, the total content of the polymer in the crosslinkable polymer formulation is in the range from 1 to 99.5% by weight, preferably from 5 to 99% by weight.

In a preferred embodiment of the present invention the Lewis acid curing catalyst which is contained in the crosslinkable polymer formulation is represented by formula (1):

MLₓ (1)

wherein M is a member of the element groups 8, 9, 10, 11 and 13 of the periodic table; L is a ligand which is at each occurrence selected independently from the group consisting of anionic ligands, neutral ligands and radical ligands; and x is an integer from 2 to 6, preferably 2 or 3.

The element groups 8, 9 and 10 are also referred to in the periodic table as group VIII and they designate the iron (Fe), cobalt (Co) and nickel (Ni) transition groups, respectively. The element group 11 is also referred to in the periodic table as group IB and it designates the copper (Cu) main group. The element group 13 is also referred to in the periodic table as group IlIA and it designates the boron (B) main group.

More preferably, M is selected from the list consisting of Fe, Ru, Os, Co, Rh, Ir, Ni, Pd, Pt, Cu, Ag, Au, B, Al, Ga, In and TI. Most preferably, M is selected from the list consisting of Ru, Ni, Pd, Pt, Cu, Ag, B, Al and Ga.

As mentioned above, L is at each occurrence independently selected from anionic ligands, neutral ligands or radical ligands. The anionic ligands and neutral ligands may be monodentate, bidentate or tridentate. The radical ligands may be monovalent, bivalent or trivalent.

Preferred anionic and neutral ligands are halides or organic ligands which coordinate M via one, two or more than two heteroatoms such as e.g. N, O, P and S.

Preferred anionic ligands are selected from the group consisting of halides, cyanide, alcoholates, carboxylates, deprotonated keto acids, deprotonated keto esters and deprotonated diketones.

Preferred halides include fluoride, chloride, bromide and iodide. Preferred alcoholates include methylate, ethylate, propylate, butylate, pentylate, hexylate, heptylate, octylate, 1,2-diolates such as ethylene glycolate, 1,3-diolates such as propylene glycolate, 1,4-diolates such as butylene glycolate, 1,5-diolates such as pentylene glycolate, and glycerolate, and their isomers. Preferred carboxylates include formate, acetate, propionate, butanoate, pentanoate, hexanoate, heptanoate, octanoate, oxalate, malonate, succinate, glutarate, adipate, oxylate, and citrate, and their isomers. Preferred deprotonated keto acids include deprotonated species derived from alpha-keto acids such as pyruvic acid, oxaloacetic acid and alpha-ketoglutaric acid, beta-keto acids such as acetoacetic acid and beta-ketoglutaric acid, and gamma-keto acids such as levulinic acid. Preferred deprotonated keto esters include deprotonated species derived from a keto acid ester such as e.g. methylacetoacetate, ethylacetoacetate, propoylacetoacetate and butyl acetoacetate. Preferred deprotonated diketones include deprotonated species derived from 1,3-diketones such as acetylacetone.

Particularly preferred anionic ligands are selected from the group consisting of acetate, propionate, acetylacetonate, cyanide and ethylacetoacetate.

Preferred neutral ligands are selected from the group consisting of alcohols and carbon monoxide.

Preferred alcohols include methanol, ethanol, propanol, butanol, pentanol, hexanol, heptanol, oxtanol, ethylene glycol, propylene glycol, butylene glycol, pentylene glycol, glycerol, and their isomers.

Particularly preferred neutral ligands are selected from the group consisting of carbon monoxide.

Radical ligands are organic ligands which coordinate M via one, two or more than two radical carbon atoms. Preferred radical ligands are selected from the group consisting of hydrogen, straight-chain alkyl having 1 to 20 carbon atoms, straight-chain alkenyl having 2 to 20 carbon atoms, branched-chain alkyl or alkenyl having 3 to 20 carbon atoms, cyclic alkyl or alkenyl having 3 to 20 carbon atoms, and aryl or heteroaryl having 4 to 18 carbon atoms, wherein one or more hydrogen atoms may be optionally replaced by F and wherein one or more non-adjacent CH₂ groups may be optionally replaced by —O—, —(C═O)— or —(C═O)—O—.

More preferably, radical ligands are selected from the group consisting of hydrogen, straight-chain alkyl having 1 to 12 carbon atoms, straight-chain alkenyl having 2 to 12 carbon atoms, branched-chain alkyl or alkenyl having 3 to 12 carbon atoms, cyclic alkyl or alkenyl having 3 to 12 carbon atoms, and aryl or heteroaryl having 4 to 10 carbon atoms, wherein one or more hydrogen atoms may be optionally replaced by F and wherein one or more non-adjacent CH₂ groups may be optionally replaced by —O—, —(C═O)— or —(C═O)—O—.

More preferably, radical ligands are selected from the group consisting of hydrogen, straight-chain alkyl having 1 to 10 carbon atoms, branched-chain alkyl having 3 to 10 carbon atoms, cyclic alkyl having 3 to 10 carbon atoms, and aryl or heteroaryl having 4 to 10 carbon atoms, wherein one or more hydrogen atoms may be optionally replaced by F and wherein one or more non-adjacent CH₂ groups may be optionally replaced by —O—, —(C═O)— or —(C═O)—O—.

Particularly preferably, radical ligands are selected from the group consisting of hydrogen, ethyl, propyl, butyl, pentyl, hexyl, heptyl, octyl, nonyl, decyl, cyclobutyl, cyclopentyl, cyclohexyl, cycloheptyl, cyclooctyl, cyclononyl, cyclodecyl, phenyl und naphthyl, which optionally may be partially of fully fluorinated.

Most preferably, radical ligands are selected from the group consisting of hydrogen, methyl, ethyl, n-propyl, iso-propyl, n-butyl, iso-butyl, sec-butyl, t-butyl, n-pentyl, 2-pentyl, 3-pentyl, 2-methylbutyl, 3-methylbutyl, 3-methylbut-2-yl, 2-methylbut-2-yl, 2,2-dimethylpropyl, n-hexyl, 2-hexyl, 3-hexyl, 2-methylpentyl, 3-methylpentyl, 4-methylpentyl, 2-methylpent-2-yl, 3-methylpent-2-yl, 2-methylpent-3-yl, 3-methylpent-3-yl, 2-ethylbutyl, 3-ethylbutyl, 2,3-dimethylbutyl, 2,3-dimethylbut-2-yl, 2,2-dimethylbutyl, n-heptyl, n-octyl, n-nonyl, n-decyl, phenyl and naphthyl, which optionally may be partially of fully fluorinated.

In a particularly preferred embodiment of the present invention the Lewis acid curing catalyst in the crosslinkable polymer formulation is selected from the group consisting of triarylboron compounds such as e.g. B(C₆H₅)₃ and B(C₆F₅)₃, triarylaluminum compounds such as e.g. Al(C₆H₅)₃ and Al(C₆F₅)₃, palladium acetate, palladium acetylacetonate, palladium propionate, nickel acetylacetonate, silver acetylacetonate, platinum acetylacetonate, ruthenium acetylacetonate, ruthenium carbonyls, copper acetylacetonate, aluminum acetylacetonate, and aluminum tris(ethyl acetoacetate).

Depending on the catalyst system used, the presence of moisture or oxygen may play a role in the curing of the coating. For instance, through the choice of a suitable catalyst system, it is possible to achieve rapid curing at high or low atmospheric humidity or at high or low oxygen content. The skilled worker is familiar with these influences and will adjust the atmospheric conditions appropriately by means of suitable optimization methods.

Preferably, the amount of the Lewis acid curing catalyst in the crosslinkable polymer formulation is ≤10 weight-%, more preferably ≤5.0 weight-%, and most preferably ≤1.00 weight-%. Preferred ranges for the amount of the curing catalyst in the crosslinkable polymer formulation are from 0.001 to 10 weight-%, more preferably from 0.001 to 5.0 weight-%, and most preferably from 0.001 to 1.00 weight-%.

Solvents suitable for the crosslinkable polymer formulation are, in particular, organic solvents which contain no water and also no reactive groups such as hydroxyl groups. These solvents are, for example, aliphatic or aromatic hydrocarbons, halogenated hydrocarbons, esters such as ethyl acetate or butyl acetate, ketones such as acetone or methyl ethyl ketone, ethers such as tetrahydrofuran or dibutyl ether, and also mono- and polyalkylene glycol dialkyl ethers (glymes), or mixtures of these solvents.

In a preferred embodiment the crosslinkable polymer formulation comprises one or more solvents.

Preferably, the formulation may comprise one or more additives selected from the group consisting of nanoparticles, converters, viscosity modifiers, surfactants, additives influencing film formation, additives influencing evaporation behavior and cross-linkers. Most preferably, said formulation further comprises a converter. Nanoparticles may be selected from nitrides, titanates, diamond, oxides, sulfides, sulfites, sulfates, silicates and carbides which may be optionally surface-modified with a capping agent. Preferably, nanoparticles are materials having a particle diameter of <100 nm, more preferably <80 nm, even more preferably <60 nm, even more preferably <40 nm, and most more preferably <20 nm. The particle diameter may be determined by any standard method known to the skilled person.

It is preferred that in step (a) of the method for preparing an optoelectronic device the crosslinkable polymer formulation is provided on a surface of an optoelectronic device precursor using an application method for applying liquid formulations. Such application methods include, for example, a method of wiping with a cloth, a method of wiping with a sponge, spray coating, flow coating, roller coating, dip coating, slot coating, dispensing, screen printing, stencile printing or ink-jet printing. Further methods include, for example, blade, spray, gravure, dip, hot-melt, roller, slot-die, printing methods, spinning or any other method.

In case of spray coating a rather high dilution is needed, typically a spray coating formulation contains a total solvent content of 70-95 weight %. Since the solvent content in spray coating formulations is very high, spray coating formulations are very sensitive to the type of solvents. It is general knowledge that spray coating formulations are made of mixtures of high and low boiling solvents (e.g. Organic Coatings: Science and Technology, Z. W. Wicks et al., page 482, 3^{rd} Edition (2007), John Wiley & Sons, Inc.).

It is further preferred that the crosslinkable polymer formulation is applied in step (a) as a layer in a thickness of 1 μm to 1 cm, more preferably of 10 m to 1 mm. In a preferred embodiment, the formulation is applied as a thin layer having a thickness of 1 to 200 μm, more preferably of 5 to 180 m and most preferably of 10 to 150 μm. In an alternative preferred embodiment, the formulation is applied as a thick layer having a thickness of 200 μm to 1 cm, more preferably of 200 μm to 5 mm and most preferably of 200 μm to 1 mm.

It is preferred that in step (b) of the method for preparing an optoelectronic device the curing is carried out at elevated temperature, preferably at a temperature selected from 0 to 300° C., more preferably from 10 to 250° C., and most preferably from 15 to 220° C.

Preferably, the curing in step (b) is carried out on a hot plate, in a furnace, or in a climate chamber. Alternatively, if articles such as trains, vehicles, ships, walls, buildings or articles of very large size are coated, the curing is preferably carried out under ambient conditions.

In a preferred embodiment, the curing in step (b) is carried out on a hot plate or in a furnace at a temperature selected from 0 to 300° C., more preferably from 10 to 250° C., and most preferably from 15 to 220° C.

In an alternative preferred embodiment, the curing in step (b) is carried out in a climate chamber having a relative humidity in the range from 50 to 99%, more preferably from 60 to 95%, and most preferably from 80 to 90%, at a temperature selected from 10 to 95° C., more preferably from 15 to 85° C., and most preferably from 20 to 85° C.

In another alternative preferred embodiment, the curing in step (b) is carried out under ambient conditions.

Preferably, the curing time is from 0.1 to 24 h, more preferably from 0.5 to 16 h, still more preferably from 1 to 8 h and most preferably from 2 to 5 h, depending on the application thickness, the composition of the polymer, and the nature of the curing catalyst.

The optoelectronic device which is obtainable by the method as described above may be an electronic devices that operate on both light and electrical currents. Preferably, the optoelectronic device obtainable by said method is a laser diode, LED, OLED, OLET (organic light emitting transistor), solar cell or photovoltaic cell.

Particular preference is given here to an LED comprising a semiconductor light source (LED chip) and at least one converter, preferably a phosphor or quantum material. The LED is preferably white-emitting or emits light having a certain color point (color-on-demand principle). The color-on-demand concept is taken to mean the production of light having a certain color point using a pc-LED (=phosphor-converted LED) using one or more phosphors. The encapsulation material forms a barrier against the external environment of the LED device, thereby protecting the converter and/or the LED chip. The encapsulating material is preferably in direct contact with the converter and/or the LED chip.

In a preferred embodiment the semiconductor light source (LED chip) contains a luminescent indium aluminum gallium nitride which preferably is of the formula InᵢGaⱼAlₖN, where 0≤i, 0≤j, 0≤k, and i+j+k=1.

In a further preferred embodiment the LED is a luminescent arrangement based on ZnO, TCO (transparent conducting oxide), ZnSe or SiC. In a further preferred embodiment the LED is a light source which exhibits electroluminescence and/or photoluminescence.

It is preferred that the crosslinked polymer material is comprised in a converter layer of the LED. Preferably, the converter layer contains the crosslinked polymer material and one or more converters which are preferably selected from phosphors and/or quantum materials.

The converter layer is either arranged directly on the semiconductor light source (LED chip) or alternatively arranged remote therefrom, depending on the respective type of application (the latter arrangement also includes “remote phosphor technology”). The advantages of remote phosphor tech-nology are known to the person skilled in the art and are revealed, for example, by the following publication: Japanese J. of Appl. Phys. Vol. 44, No. 21 (2005), L649-L651.

The optical coupling between the semiconductor light source (LED chip) and the converter layer can also be achieved by a light-conducting arrange-ment. This makes it possible for the semiconductor to be installed at a cen-tral location and to be optically coupled to the converter layer by means of light-conducting devices, such as, for example, optical fibres. In this way, it is possible to achieve lamps adapted to the lighting wishes which merely consist of one or various phosphors, which can be arranged to form a light screen, and an optical waveguide, which is coupled to the light source. In this way, it is possible to place a strong light source at a location which is favourable for electrical installation and to install lamps comprising phos-phors which are coupled to the optical waveguides at any desired locations without further electrical cabling, but instead only by laying optical wave-guides.

Preferably, the converter is a phosphor, i.e. a substance having luminescent properties. The term “luminescent” is intended to include both, phosphorescent as well as fluorescent.

For the purposes of the present application, the type of phosphor is not particularly limited. Suitable phosphors are well known to the skilled person and can easily be obtained from commercial sources. For the purposes of the present application the term “phosphor” is intended to include materials that absorb in one wavelength of the electromagnetic spectrum and emit at a different wavelength.

Examples of suitable phosphors are inorganic fluorescent materials in particle form comprising one or more emitting centers. Such emitting centers may, for example, be formed by the use of so-called activators, which are preferably atoms or ions selected from the group consisting of rare earth elements, transition metal elements, main group elements and any combination of any of these. Example of suitable rare earth elements may be selected from the group consisting of La, Ce, Pr, Nd, Pm, Sm, Eu, Gd, Tb, Dy, Ho, Er, Tm, Yb and Lu. Examples of suitable transition metal elements may be selected from the group consisting of Cr, Mn, Fe, Co, Ni, Cu, Ag, Au and Zn. Examples of suitable main group elements may be selected from the group consisting of Na, TI, Sn, Pb, Sb and Bi. Examples of suitable phosphors include phosphors based on garnet, silicate, orthosilicate, thiogallate, sulfide, nitride, silicon-based oxynitride, nitridosilicate, nitridoaluminumsilicate, oxonitridosilicate, oxonitridoaluminumsilicate and rare earth doped sialon.

Phosphors which may be employed as a converter in the converting layer of an LED are, for example: Ba₂SiO₄:Eu²⁺, BaSi₂O₅:Pb²⁺, BaₓSr₁₋ₓF₂:Eu²⁺ (with 0≤x≤1), BaSrMgSi₂O₇:Eu²⁺, BaTiP₂O₇, (Ba,Ti)₂P₂O₇:Ti, Ba₃WO₆:U, BaY₂F₈:Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺, Mn²⁺, CaAl₂O₄:Tb³⁺, Ca₃Al₂Si₃O₁₂:Ce³⁺, Ca₃Al₂Si₃O₁₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺, Mn²⁺ in SiO₂, CaF₂:Ce³⁺, CaF₂:Ce³⁺,Mn²⁺, CaF₂:Ce³⁺, Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺,Mn²⁺ in SiO₂, CaLaBO₄:Eu³⁺, CaLaB₃O₇:Ce³⁺,Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺,Mn²⁺, Ca₂MgSi₂O₇:Eu²⁺,Mn²⁺, CaMoO₄, CaMoO₄:Eu³⁺, CaO:Bi³⁺, CaO:Cd²⁺, CaO:Cu+, CaO:Eu³⁺, CaO:Eu³⁺, Na+, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺,Mn²⁺, Ca₅(PO₄)₃F:Mn²⁺, Ca₅(PO₄)₃F:Sb³⁺, Ca₅(PO₄)₃F:Sn²⁺, α-Ca₃(PO₄)₂:Eu²⁺, R³—Ca₃(PO₄)₂:Eu²⁺, Ca₂P₂O₇:Eu²⁺, Ca₂P₂O₇:Eu²⁺,Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu+,Na+, CaS:La³⁺, CaS:Mn²⁺, CaSO₄:Bi, CaSO₄:Ce³⁺, CaSO₄:Ce³⁺,Mn²⁺, CaSO₄:Eu²⁺, CaSO₄:Eu²⁺,Mn²⁺, CaSO₄:Pb²⁺, CaS:Pb²⁺, CaS:Pb²⁺,Cl, CaS:Pb²⁺,Mn²⁺, CaS:Pr³⁺,Pb²⁺,Cl, CaS:Sb³⁺, CaS:Sb³⁺,Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺,Pb, CaSiO₃:Pb²⁺, CaSiO₃:Pb²⁺,Mn²⁺, CaSiO₃:Ti⁴⁺, CaSr₂(PO₄)₂:Bi³⁺, β-(Ca,Sr)₃(PO₄)₂:Sn²⁺ Mn²⁺, CaTi_{0.9}Al_{0.1}O₃:Bi³⁺, CaTiO₃:Eu³⁺, CaTiO₃:Pr³⁺, Ca₅(VO₄)₃C₁, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag+,Cr, CdS:In, CdS:In, CdS:In,Te, CdS:Te, CdWO₄, CsF, CsI, CsI:Na+, CsI:TI, (ErCl₃)_{0.25}(BaCl₂)_{0.75}, GaN:Zn, Gd₃Ga₅O₁₂:Cr³⁺, Gd₃Ga₅O₁₂:Cr,Ce, GdNbO₄:Bi³⁺, Gd₂O₂S:Eu³⁺, Gd₂O₂SPr³⁺, Gd₂O₂S:Pr,Ce,F, Gd₂O₂S:Tb³⁺, Gd₂SiO₅:Ce³⁺, KA₁₁O₁₇:TI+, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAIB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb) PO₄:Ce:Tb, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺,Tb³⁺, LaVO₄:Eu³⁺, La₂W₃O₁₂:Eu³⁺, LiAIF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁_,Y,AlO₃:Ce³⁺ (with 0≤x≤1), MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺,Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAl₁₁O₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, (Mg,Sr)Ba₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:TI, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}KO₄₆Er_{0.08}TiSi₄O₁₁Eu³⁺, Na₂Mg₃Al₂Si₂O₁₀:Tb, Na(Mg₂₋ₓMnₓ)LiSi₄O₁₀F₂:Mn (with 0≤x≤2), NaYF₄:Er³⁺, Yb³⁺, NaYO₂:Eu³⁺, P₄₆(70%)+P₄₇ (30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺ (F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}:Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺, Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺,Cl, β-SrO.3B₂O₃:Pb²⁺, β-SrO.3B₂O₃:Pb²⁺,Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺, Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺,Mn²⁺ (Al), SrS:Ce³⁺, SrS:Eu²⁺, SrS:Mn²⁺, SrS:Cu⁺,Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃:Pr³⁺, SrTiO₃:Pr³⁺,Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺,Cr³⁺, YAl₃B₄O₁₂:Th⁴⁺,Ce³⁺,Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu^{3r}, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺,Yb³⁺, YF₃:Mn²⁺, YF₃:Mn²⁺,Th⁴⁺, YF₃:Tm³⁺,Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBr:Eu³⁺, Y₂O₃:Ce, Y₂O₃:Er³⁺, Y₂O₃:Eu³⁺ (YOE), Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺,Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺,Cl⁻, ZnS:Ag,Cu,Cl, ZnS:Ag,Ni, ZnS:Au,ln, ZnS—CdS (25-75), ZnS—CdS (50-50), ZnS—CdS (75-25), ZnS—CdS:Ag,Br,Ni, ZnS—CdS:Ag+,Cl, ZnS—CdS:Cu,Br, ZnS—CdS:Cu,I, ZnS:Cl⁻, ZnS:Eu²⁺, ZnS:Cu, ZnS:Cu+,Al³⁺, ZnS:Cu,Cl⁻, ZnS:Cu,Sn, ZnS:Eu²⁺, ZnS:Mn²⁺, ZnS:Mn,Cu, ZnS:Mn²⁺,Te²⁺, ZnS:P, ZnS:P³⁻,Cl⁻, ZnS:Pb²⁺, ZnS:Pb²⁺,Cl⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn,Sb₂O₂, Zn₂SiO₄:Mn²⁺,P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu+,Cl and/or ZnWO₄.

Preferably, an LED precursor contains a semiconductor light source (LED chip) and/or lead frame and/or gold wire and/or solder (flip chip). The LED precursor may further optionally contain a converter and/or a primary optic and/or a secondary optic. The converter layer may be arranged either directly on a semiconductor light source (LED chip) or alternatively remote therefrom, depending on the respective type of application. The encapsulation material forms a barrier against the external environment of the LED device, thereby protecting the converter and/or the LED chip. The encapsulation material is preferably in direct contact with the converter and/or the LED chip.

It is preferred that the crosslinkable polymer formulation which is applied to an LED precursor forms part of a converter layer. It may be further preferred that the converter layer is in direct contact to an LED chip or is arranged remote therefrom.

Preferably, the converter layer further comprises one or more converters such as a phosphor and/or quantum material as defined above.

LEDs prepared according to the method of the present invention may, for example, be used for backlights for liquid crystal (LC) displays, traffic lights, outdoor displays, billboards, general lighting, to name only a few non-limiting examples.

Typical LEDs may be prepared similarly to the ones described in U.S. Pat. No. 6,274,924 B₁ and U.S. Pat. No. 6,204,523 BI. Moreover, a LED filament as described in US 2014/0369036 A1 may be prepared using the present crosslinkable polymer formulation as a package adhesive layer. Such LED filaments include a substrate, a light emitting unit secured onto at least one side surface of the substrate, and a package adhesive layer surrounded on the periphery of the light emitting unit. The substrate is configured to be of an elongated bar construction. The emitting unit includes a plurality of blue light chips and red light chips regularly distributed on the substrate and sequentially connected to one another in series. The package adhesive layer is made from the encapsulation material according to the present invention containing a converter.

The present invention further relates to a crosslinkable polymer formulation comprising a polymer, and a Lewis acid curing catalyst; wherein the polymer is a polysiloxazane containing a repeating unit M¹ and a repeating unit M³, wherein the repeating unit M¹ is represented by formula (I) and the repeating unit M³ is represented by formula (III):

-[—SiR¹R²—NR³—]- (I)

-[—SiR⁷R—[O—SiR⁷R⁸—]ₐ—NR⁹—]- (III)

wherein R¹, R², R³, R⁷, R⁸ and R⁹ are independently from each other selected from the group consisting of hydrogen, organyl and organoheteryl, and a is an integer from 1 to 60, preferably from 1 to 50. More preferably, a may be an integer from 5 to 50 (long chain monomer M³); or a may be an integer from 1 to 4 (short chain monomer M³).

In a preferred embodiment R¹, R², R³, R⁷, R⁸ and R⁹ are independently from each other selected from the group consisting of hydrogen, alkyl having 1 to 40 carbon atoms, alkenyl having 2 to 40 carbon atoms and aryl having 6 to 30 carbon atoms. More preferably, R¹, R², R³, R⁷, R⁸ and R⁹ are independently from each other selected from the group consisting of hydrogen, alkyl having 1 to 20 carbon atoms, alkenyl having 2 to 20 carbon atoms and phenyl. Most preferably, R¹, R², R³, R⁷, R⁸ and R⁹ are independently from each other hydrogen, methyl or vinyl.

In a preferred embodiment, the polymer contains besides the repeating units M¹ and M³ a further repeating unit M² which is represented by formula (II):

-[—SiR⁴R⁵—NR⁶—]- (II)

wherein R⁴, R⁵ and R⁶ are at each occurrence independently from each other selected from the group consisting of hydrogen, organyl and organoheteryl; and wherein M² is different from M¹.

It is preferred that R⁴, R⁵ and R⁶ in formula (II) are independently from each other selected from the group consisting of hydrogen, alkyl having 1 to 40 carbon atoms, alkenyl having 2 to 40 carbon atoms and aryl having from 6 to 30 carbon atoms. More preferably, R⁴, R⁵ and R⁶ are independently from each other selected from the group consisting of hydrogen, alkyl having 1 to 20 carbon atoms, alkenyl having 2 to 20 carbon atoms and phenyl. Most preferably, R⁴, R⁵ and R⁶ are independently from each other hydrogen, methyl or vinyl.

Further preferred substituents R¹, R², R³, R⁴, R⁵, R⁶, R⁷, R⁸ and R⁹ are the same as described above in connection with the crosslinkable polymer formulation used in the method for preparing an optoelectronic device.

In a preferred embodiment of the crosslinkable polymer formulation according to the present invention the Lewis acid curing catalyst is represented by formula (1):

MLₓ (1)

wherein M is a member of the element groups 8, 9, 10, 11 and 13 of the periodic table; L is a ligand which is at each occurrence selected independently from the group consisting of anionic ligands, neutral ligands and radical ligands; and x is an integer from 2 to 6, preferably 2 or 3.

The element groups 8, 9 and 10 are also referred to in the periodic table as group VIII and they designate the iron (Fe), cobalt (Co) and nickel (Ni) transition groups, respectively. The element group 11 is also referred to in the periodic table as group IB and it designates the copper (Cu) main group. The element group 13 is also referred to in the periodic table as group IlIA and it designates the boron (B) main group.

More preferably, M is selected from the list consisting of Fe, Ru, Os, Co, Rh, Ir, Ni, Pd, Pt, Cu, Ag, Au, B, Al, Ga, In and TI. Most preferably, M is selected from the list consisting of Ru, Ni, Pd, Pt, Cu, Ag, B, Al and Ga.

Preferred ligands L are the same as described above in connection with the crosslinkable polymer formulation used in the method for preparing an optoelectronic device.

In a particularly preferred embodiment the Lewis acid curing catalyst in the crosslinkable polymer formulation according to the present invention is selected from the group consisting of triarylboron compounds such as e.g. B(C₆H₅)₃ and B(C₆F₅)₃, triarylaluminum compounds such as e.g. Al(C₆H₅)₃ and Al(C₆F₅)₃, palladium acetate, palladium acetylacetonate, palladium propionate, nickel acetylacetonate, silver acetylacetonate, platinum acetylacetonate, ruthenium acetylacetonate, ruthenium carbonyls, copper acetylacetonate, aluminum acetylacetonate, and aluminum tris(ethyl acetoacetate).

In a particularly preferred embodiment of the present invention the Lewis acid curing catalyst in the crosslinkable polymer formulation is selected from the group consisting of triarylboron compounds such as e.g. B(C₆H₅)₃ and B(C₆F₅)₃, triarylaluminum compounds such as e.g. Al(C₆H₅)₃ and Al(C₆F₅)₃, palladium acetate, palladium acetylacetonate, palladium propionate, nickel acetylacetonate, silver acetylacetonate, platinum acetylacetonate, ruthenium acetylacetonate, ruthenium carbonyls, copper acetylacetonate, aluminum acetylacetonate, and aluminum tris(ethyl acetoacetate).

Depending on the catalyst system used, the presence of moisture or of oxygen may play a role in the curing of the coating. For instance, through the choice of a suitable catalyst system, it is possible to achieve rapid curing at high or low atmospheric humidity or at high or low oxygen content. The skilled worker is familiar with these influences and will adjust the atmospheric conditions appropriately by means of suitable optimization methods.

Preferably, the amount of the Lewis acid curing catalyst in the crosslinkable polymer formulation according to the present invention is ≤10 weight-%, more preferably ≤5.0 weight-%, and most preferably ≤1.00 weight-%. Preferred ranges for the amount of the curing catalyst in the crosslinkable polymer formulation are from 0.001 to 10 weight-%, more preferably from 0.001 to 5.0 weight-%, and most preferably from 0.001 to 1.00 weight-%.

Solvents suitable for the crosslinkable polymer formulation according to the present invention are, in particular, organic solvents which contain no water and also no reactive groups such as hydroxyl groups. These solvents are, for example, aliphatic or aromatic hydrocarbons, halogenated hydrocarbons, esters such as ethyl acetate or butyl acetate, ketones such as acetone or methyl ethyl ketone, ethers such as tetrahydrofuran or dibutyl ether, and also mono- and polyalkylene glycol dialkyl ethers (glymes), or mixtures of these solvents.

Preferably, the formulation of the present invention may comprise one or more additives selected from the group consisting of nanoparticles, converters, viscosity modifiers, surfactants, additives influencing film formation, additives influencing evaporation behavior and cross-linkers. Most preferably, said formulation further comprises a converter. Nanoparticles may be selected from nitrides, titanates, diamond, oxides, sulfides, sulfites, sulfates, silicates and carbides which may be optionally surface-modified with a capping agent. Preferably, nanoparticles are materials having a particle diameter of <100 nm, more preferably <80 nm, even more preferably <60 nm, even more preferably <40 nm, and most more preferably <20 nm. The particle diameter may be determined by any standard method known to the skilled person.

The crosslinkable formulation of the present invention may be prepared by mixing the polymer with the Lewis acid curing catalyst. In a preferred embodiment the Lewis acid curing catalyst is added to the polymer and then mixed. In an alternative preferred embodiment the polymer is added to the curing catalyst and then mixed. The polymer and/or the Lewis acid catalyst may be present in a solution. It is preferred that the formulation of the invention is prepared at ambient temperature. Ambient temperature refers to a temperature selected from the range of 20 to 25° C. However, the formulation may also be prepared at temperatures of >25° C., preferably >25° C. to 50° C.

In addition, a method for preparing an article comprising a crosslinked polymer material as technical coating is provided, wherein the technical coating is prepared from a crosslinkable polymer formulation according to the present invention and wherein the method comprises the following steps: (a) applying a crosslinkable polymer formulation of the present invention to a support; (b) and curing said crosslinkable polymer formulation.

The curing of the coating could be done under various conditions. A temperature range starting from room temperature up to very high temperature is possible. For example to convert organopolysil(ox)azanes to ceramic material for corrosion resistant coatings on metal substrates, temperatures higher than 1000° C. are used. As an alternative to temperature curing, radiation curing by UV-light, visible light, IR radiation or other radiation sources is possible too. Some surfaces or substrates are damaged by rough conditions and therefore curing at ambient conditions is preferred. In some applications, for example coating of train wagons or buildings, only ambient condition curing is possible. Therefore there is a big need to develop formulations which can be cured under ambient conditions in a short time.

Generally coatings based on organopolysil(ox)azanes contain additional additives. For example surface active additives for better adhesion to surface, levelling of the surface, or to change properties of the surface by migrating to the surface during curing. Another purpose of surface active substances is to keep fillers homogenously dispersed in the formulation. Other additives are for example polymers. They could be used as rheological modifiers, e.g. thickener, to change the physical properties of the film: e.g. add flexibility, as crosslinking agents e.g. functional polymers with epoxy groups for faster and more efficient curing and functional polymers like fluorinated polymers or hydrophilic polymers to impart oleophobic, hydrophobic or hydrophilic properties. Other additives are fillers which can impart additional properties. For example, pigments for optical effects (color, refractive index, pearlescent effect), functional pigments for electrical and thermal conductivity, inorganic particles to reduce the thermal expansion which allows higher film thicknesses by reduced tendency of crack formation, hard particles for improved hardness or scratch resistance.

In addition to these components, technical coating formulations usually comprise one or more solvents.

Preferred embodiments of the method for preparing an article are the same as described above in connection with the method for preparing an optoelectronic device.

Preferred supports on which the crosslinkable polymer formulation may be applied in step (a) are selected from the group consisting of automobile bodies, automobile wheels, dentures, tombstones, the interior and exterior of a house, products used with water in toilets, kitchens, washrooms, bathtubs, etc., toilet stools, signboards, signs, plastic products, glass products, ceramic products and wood products. The support materials to which the crosslinkable polymer formulation of the invention is applied include a wide variety of materials, for example metals such as iron, steel, silver, zinc, aluminum, nickel, titanium, vanadium, chromium, cobalt, copper, zirconium, niobium, molybdenum, ruthenium, rhodium, silicon, boron, tin, lead or manganese or alloys thereof provided, if necessary, with an oxide or plating film; and various kinds of plastics such as polymethyl methacrylate (PMMA), polyurethane, polyesters such as PET, polyallyldiglycol carbonate (PADC), polycarbonate, polyimide, polyamide, epoxy resin, ABS resin, polyvinyl chloride, polyethylene, polypropylene, polythiocyanate, POM and polytetrafluoroethylene, if necessary, in combination with a primer to enhance the adhesion to the said materials. Such primers are for instance silanes, siloxane, silazane to name only a few. If plastic materials are used, it could be advantageous to perform a pretreatment by flaming, corona or plasma treatment, this might improve the adhesion of the coating. Further support materials include glass, wood, ceramics, concrete, mortar, marble, brick, clay or fibers etc. These materials may be coated, if necessary, with lacquers, varnishes or paints such as polyurethane lacquers, acrylic lacquers and/or dispersion paints.

The technical coating which is prepared from the crosslinkable polymer formulation forms a rigid and dense coating excellent in adhesion to a support material and may form a coating excellent in corrosion resistance and anti-scratch properties and simultaneously excellent in characteristics such as long-lasting hydrophilic and anti-fouling effect, abrasion resistance, easy-to-clean properties, anti-scratch properties, corrosion resistance, sealing properties, chemical resistance, oxidation resistance, physical barrier effect, low shrinkage, UV-barrier effect, smoothening effect, durability effect, heat resistance, fire resistance and antistatic properties on the surfaces of various support materials.

There is further provided an article comprising the crosslinked polymer composition as a technical coating such as e.g. a protective surface coating or a functional coating. The article can be made of any of the support materials mentioned above. Preferably, the protective surface coating is applied on an article made of metal, polymer, glass, wood, stone or concrete which may optionally have a primary coating underneath the protective surface coating.

The present invention is further illustrated by the examples following hereinafter which shall in no way be construed as limiting. The skilled person will acknowledge that various modifications, additions and alternations may be made to the invention without departing from the spirit and scope of the invention as defined in the appended claims.

### EXAMPLES

### Example 1

Organopolysilazane Durazane 1033 (silazane of structure (I), n:m=33:67) (10 g) is mixed with a 10% solution of triphenylaluminum solution in THF (1 g). The mixture is poured on a glass plate to form a film having a thickness of ca. 1-2 μm and stored at ambient conditions. A reference glass plate with a film obtained from a mixture of Organopolysilazane Durazane 1033 (10 g) and THF (1 g) (no catalyst) is prepared and stored in parallel. After 4 h the material containing the catalyst is dry to touch, while the reference material is still liquid. Both glass plates are heated on a hot plate at 150° C. for 8 h and analyzed by FT-IR. In the following, the glass plates are heated for additional 8 h at 220° C. on a hot plate and again analyzed by FT-IR. The FT-IR spectra clearly show a higher degree of hydrolysis/crosslinking for the catalyst containing material in comparison to the catalyst free material (see FIG. 1).

-[—Si(CH₃)₂—NH-]ₙ-[—Si(CH₃)H—NH-]ₘ- (I)

### Example 2

Perhydropolysilazane NN-120-20 (20% silazane of structure (II) dissolved in di-n-butyl ether) (10 g) is mixed with a 10% solution of B(C₆H₅)₃ in THF (0.2 g). The mixture is poured on a glass plate to form a film having a thickness of ca. 0.1-0.2 μm and stored at ambient conditions. A reference glass plate with a film obtained from a mixture of the Perhydropolysilazane (10 g) and THF (0.2 g) (no catalyst) is prepared and stored in parallel. After 4 h the material containing the catalyst is dry to touch, while the reference material is still liquid

-[—SiH₂—NH-]ₙ- (II)

### Example 3

Experiments with Organopolysilazanes Cured at Different Conditions

Materials

Material A: Durazane 1033*, molecular weight 2,300 g/mol

Material B: Durazane 1066*, molecular weight 1,800 g/mol

Material C: Durazane 1050*, molecular weight 4,500 g/mol

Material D: Siloxazane 2020**, molecular weight 5,600 g/mol

*available from MERCK KGaA

**synthesis of Siloxazane 2020 is described in Example X

Conditions

Condition I: ambient conditions, 25° C. and controlled relative humidity of 50%

Condition II: open hot plate, 85° C. and controlled relative humidity of 50%

Condition III: climate chamber, 85° C. and controlled relative humidity of 85%

Catalysts

Catalyst 1: DBU=1,8-diazabicyclo[5.4.0]undec-7-ene (as reference)

Catalyst 2: AlPh₃=triphenylaluminum

Catalyst 3: Al(AcAc)₃=aluminum acetylacetoate

Catalyst 4: B(C₆F₅)₃=tris(pentafluorophenyl) borane

Catalyst 5: Pt(AcAc)₂=platinum(II) acetylacetonate

Test Procedure

The material is mixed with the respective catalyst in a weight ratio of 99.5:0.5. As reference, the pure material is tested without catalyst. A film of 40-60 μm thickness is applied on a glass plate by doctor-blade coating. The glass plate is then stored under the conditions as described above and stickiness is checked repeatedly in fixed intervals of time. Tables 1 to 3 indicate the shortest time in hours at which the coating is dry-to-touch.

TABLE 1
Conditions I

| | Time | Time | Time | Time | Time | Time |
|---|---|---|---|---|---|---|
| Mate- | [h] | [h] | [h] | [h] | [h] | [h] |
| rial | no cat. | Cat. 1 | Cat. 2 | Cat. 3 | Cat. 4 | Cat. 5 |
| A | >24 | 18 | 3 | 2 | 3 | 5 |
| B | >24 | >24 | 6 | 4 | 6 | 10 |
| C | >24 | 20 | 4 | 2 | 4 | 6 |
| D | >24 | >24 | 7 | 4 | 5 | 8 |

TABLE 2
Conditions II

| | Time | Time | Time | Time | Time | Time |
|---|---|---|---|---|---|---|
| Mate- | [h] | [h] | [h] | [h] | [h] | [h] |
| rial | no cat. | Cat. 1 | Cat. 2 | Cat. 3 | Cat. 4 | Cat. 5 |
| A | >24 | 12 | 1 | 1 | 2 | 4 |
| B | >24 | >24 | 2 | 2 | 3 | 7 |
| C | >24 | 16 | 1 | 1 | 2 | 5 |
| D | >24 | >24 | 2 | 2 | 3 | 6 |

TABLE 3
Conditions III

| | Time | Time | Time | Time | Time | Time |
|---|---|---|---|---|---|---|
| Mate- | [h] | [h] | [h] | [h] | [h] | [h] |
| rial | no cat. | Cat. 1 | Cat. 2 | Cat. 3 | Cat. 4 | Cat. 5 |
| A | 16 | 10 | 1 | 1 | 2 | 4 |
| B | >24 | >24 | 2 | 2 | 3 | 5 |
| C | 24 | 20 | 1 | 1 | 2 | 4 |
| D | >24 | >24 | 2 | 1 | 2 | 6 |

These results show the effect of the catalyst addition on the curing rate of organopolysilazanes. As expected, the curing rate at higher temperatures and in climate chamber atmosphere is faster than at ambient conditions.

### Example 4

Experiments with Organopolysilazanes and Filler

Materials

Material A: Durazane 1033*, molecular weight 2,300 g/mol

*available from MERCK KGaA

Filler X: 5 μm glass powder (available from Schott AG)

Filler Y: Phosphor (Isiphor® YYG 545 200, available from MERCK KGaA)

Filler Z: Pigment (Xirallic, available from MERCK KGaA)

Conditions

Condition I: ambient conditions, 25° C. and controlled relative humidity of 50%

Condition II: open hot plate, 85° C. and controlled relative humidity of 50%

Condition III: climate chamber, 85° C. and controlled relative humidity of 85%

Catalyst

Catalyst 6: BPh₃=triphenylborane

Test Procedure:

Material A is mixed with the Catalyst 6 in a weight ratio of 99.5:0.5. Then, 70 weight-% of the respective filler material is added. As a reference, the pure Material A and respective filler material are used. A film of 80-100 m thickness is applied on a glass plate by doctor-blade coating. The glass plate is stored under the conditions as described above and stickiness is checked repeatedly in fixed intervals of time. Table 4 to 6 indicate the shortest time in hours at which the coating is dry-to-touch.

TABLE 4
Conditions I

| | | Time [h] | Time [h] |
|---|---|---|---|
| Material | Filler | no cat. | Cat. 6 |
| A | X | >24 | 3 |
| A | Y | >24 | 3 |
| A | Z | >24 | 3 |

TABLE 5
Conditions II

| | | Time [h] | Time [h] |
|---|---|---|---|
| Material | Filler | no cat. | Cat. 6 |
| A | X | >24 | 2 |
| A | Y | >24 | 2 |
| A | Z | >24 | 2 |

TABLE 6
Conditions III

| | | Time [h] | Time [h] |
|---|---|---|---|
| Material | Filler | no cat. | Cat. 6 |
| A | X | 16 | <1 |
| A | Y | 16 | <1 |
| A | Z | 16 | <1 |

These results show the effect of the catalyst addition on the curing rate of organopolysilane formulations containing filler particles.

### Example 5

Experiments with organopolysilazanes and high temperature curing

Materials

Material C: Durazane 1050*, molecular weight 4,500 g/mol

*available from MERCK KGaA

Catalyst

Catalyst 3: Al(AcAc)₃=aluminum acetylacetoate

Material C is mixed with Catalyst 3 in a weight ratio of 99.5:0.5. As a reference, pure Material C is used. A film of 80-100 μm thickness is applied on a glass plate by doctor-blade coating. The glass plate is heated to 150° C. for 16 h and a FT-IR is measured. The glass plate is then heated to 220° C. for 8 h and a further FT-IR is measured (see FIG. 2).

The FT-IR spectra in FIG. 2 show the higher conversion of the silazane in the presence of the catalyst. At 150° C. with catalyst the conversion is higher when compared to 220° C. without catalyst.

### Example 6

Experiments with Organopolysilazane on LED Device as Phosphor Encapsulant:

To show its usefulness for LED devices, a catalyst was tested on an Excelitas LED package. Durazane 1050 is mixed with a phosphor (Isiphor® YYG 545 200, available from MERCK KGaA) in a weight ratio of 1:2.5, diluted with ethylacetate and sprayed on a LED package (available from Excelitas). In one experiment pure Durazane 1050 is used and in a second experiment Durazane 1050 containing 0.5 weight-% Al(AcAc)₃ is used. One LED is cured at 150° C. for 4 h and another one at 200° C. for 4 h. The LEDs are then operated at a current of 1.5 A at ambient conditions for 1000 h and the change in color coordinates (Δx and Δy) is measured. The target is no or at least a very small change in color coordinates (lower change is better) (see Table 7).

TABLE 7
Deviation of color point

| | | Δx/Δy |
|---|---|---|
| Entry | Material | after 1000 h⁽¹⁾ |
| 1 | Durazane 1500, cured at 150° C. for 4 h | +0.012/+0.017 |
| 2 | Durazane 1500, cured at 200° C. for 4 h | +0.004/+0.006 |
| 3 | Durazane 1500 + Al(AcAc)₃, cured at | +0.004/+0.005 |
| | 150° C. for 4 h | |
| 4 | Durazane 1500 + Al(AcAc)₃, cured at | ≤+/−0.001/+0.002 |
| | 200° C. for 4 h | |

⁽¹⁾Measurement error = +/−0.001

The comparison of entries 1 and 3, and of entries 2 and 4 shows an improved color stability by addition of the catalyst at both curing temperatures of 150 and 200° C. There is either the possibility of maintaining the same color stability and reducing the curing temperature from 200 to 150° C. by adding a catalyst (see entry 3 vs. entry 2) or the possibility of obtaining an improved color stability and maintaining a curing temperature of 200° C. by adding a catalyst (see entry 4 vs. entry 2).

### Example 7

Use of Polysiloxazanes in Combination with a Boron Lewis Acid Curing Catalyst in Technical Coatings

Synthesis of Siloxazane 2020

A 4 l pressure vessel was charged with 1500 g of liquid ammonia at 0° C. and a pressure of between 3 bar and 5 bar. A mixture of 442 g dichloromethylsilane and 384 g 1,3-dichlorotetramethyldisiloxane were slowly added over a period of 3 h. After stirring the resulting reaction mixture for an additional 3 h the stirrer was stopped and the lower phase was isolated and evaporated to remove dissolved ammonia. After filtration 429 g of a colorless viscous oil remained. 100 g of this oil were dissolved in 100 g 1,4-dioxane and cooled to 0° C. 100 mg KH were added and the reaction solution was stirred for 4h, until gas formation stopped. 300 mg chlorotrimethylsilane and 250 g xylene were added and the temperature was raised to room temperature. The turbid solution was filtrated and the resulting clear solution was reduced to dryness at a temperature of 50° C. under a vacuum of 20 mbar or less. 95 g of a colorless highly viscous oil of Siloxazane 2020 remained.

Synthesis of Siloxazane 2025

A 2 l flask was charged under nitrogen atmosphere with 1000 g n-heptane, 50 g dichloromethylsilane (available from Sigma-Aldrich) and 30 g silanol-terminated polydimethylsiloxane (molecular weight Mₙ of 550 g/mol; avail-able from Sigma-Aldrich). At a temperature of 00° C. ammonia was slowly bubbled through the solution for 6 h. Precipitation of ammonium chloride was observed. The solid ammonium chloride was removed by filtration, yielding a clear filtrate, from which the solvent was removed by evaporation under reduced pressure. 49 g of a colorless low viscous liquid of Siloxazane 2025 was obtained.

Preparation

Triphenylborane (BPh₃, 1 mol/l in dibutyl ether, available from Sigma Aldrich) is diluted with tert-butyl acetate or n-butyl acetate to a concentra-tion of 5 weight-%. The catalyst solution is then mixed with the polysiloxa-zane in a ratio as shown in Table 8 and additional solvent using a dissolver (Disperlux) for 5 min at 500 rpm.

TABLE 8
Ratio of polysiloxazane and triphenylborane

| Amount [g] | Component |
|---|---|
| 80 | Siloxazane 2020 or |
| | Siloxazane 2025 |
| 20 | 5% Triphenylborane catalyst solution |
| | in THF/n-butyl acetate |

Application

The coatings are applied on the surface of a polypropylene and aluminum substrate. Prior to the coating process, the surfaces have to be cleaned with isopropanol to remove grease and dust. By doctor blade coating a layer of 3-4 μm thickness is applied on the substrates.

Evaluation

Then the substrates are stored at 22° C.+/−1° C. and a relative humidity of 50%+/−1%. The curing state is tested by touching the surface and checking the stickiness of the surface. The coating is regarded as fully cured, if it is no longer sticky. This state is called “DDT=dry-to-touch”. In Table 9 the time period in minutes is shown until the DDT state is reached, for both substrates and both polysiloxazanes with and without catalyst.

TABLE 9
Curing conditions: 22° C. and 50% relative humidity

| | | “Dry to touch” (DTT) |
|---|---|---|
| Polysiloxazane | Substrate | time period [min] |
| Siloxazane 2020 | Polypropylene | >240 |
| Siloxazane 2020 + Catalyst | Polypropylene | 30 |
| Siloxazane 2020 | Aluminum | >240 |
| Siloxazane 2020 + Catalyst | Aluminum | 30 |
| Siloxazane 2025 | Polypropylene | >240 |
| Siloxazane 2025 + Catalyst | Polypropylene | 45 |
| Siloxazane 2025 | Aluminum | >240 |
| Siloxazane 2025 + Catalyst | Aluminum | 45 |

The results in Table 2 show that the catalyst accelerates the curing of the polysiloxazanes so that the curing time required for a particular result is reduced. The results further show that the curing speed is independent of the substrate.

In order to study the impact of the curing conditions, the curing of material B on the aluminum substrate is repeated in a climate chamber of 60° C. and a relative humidity of 60% (see Table 10).

TABLE 10
Curing conditions: 60° C. and 60% relative humidity

| | | “Dry to touch” (DTT) |
|---|---|---|
| Polysiloxazane | Substrate | time period [min] |
| Siloxazane 2025 | Aluminum | 190 |
| Siloxazane 2025 + Catalyst | Aluminum | 15 |

At higher temperature and humidity, the curing of the formulation with and without catalyst is faster. However, the curing time of the formulation containing the catalyst is reduced by a factor of three when compared to the curing conditions shown in Table 9.

1. A method for preparing an optoelectronic device comprising a crosslinked polymer material which is prepared from a crosslinkable polymer formulation, wherein the method comprises the following steps:
(a) applying a crosslinkable polymer formulation to a precursor of an optoelectronic device; and
(b) curing said crosslinkable polymer formulation;
characterized in that the crosslinkable polymer formulation comprises a polymer which contains a silazane repeating unit M¹, and
a Lewis acid curing catalyst.

2. The method for preparing an optoelectronic device according to claim 1,
wherein the silazane repeating unit M¹ is represented by formula (I):
-[—SiR¹R²—NR³—]- (I)
wherein R¹, R² and R³ are independently from each other selected from the group consisting of hydrogen, organyl and organoheteryl.

3. The method for preparing an optoelectronic device according to claim 2,
wherein R¹, R² and R³ in formula (I) are independently from each other selected from the group consisting of hydrogen, alkyl having 1 to 40 carbon atoms, alkenyl having 2 to 40 carbon atoms and aryl having from 6 to 30 carbon atoms.

4. The method for preparing an optoelectronic device according to claim 1,
wherein the polymer contains a further silazane repeating unit M², wherein M² is represented by formula (II):
-[—SiR⁴R⁵—NR⁶—]- (II)
wherein R⁴, R⁵ and R⁶ are independently from each other selected from the group consisting of hydrogen, organyl and organoheteryl; and
wherein M² is different from M¹.

5. The method for preparing an optoelectronic device according to claim 4,
wherein R⁴, R⁵ and R⁶ in formula (II) are independently from each other selected from the group consisting of hydrogen, alkyl having 1 to 40 carbon atoms, alkenyl having 2 to 40 carbon atoms and aryl having from 6 to 30 carbon atoms.

6. The method for preparing an optoelectronic device according to claim 1,
wherein the polymer contains a further repeating unit M³, wherein M³ is represented by formula (III):
-[—SiR⁷R⁸—[O—SiR⁷R⁸-]ₐ-NR⁹—]- (III)
wherein R⁷, R⁸, R⁹ are independently from each other selected from the group consisting of hydrogen, organyl and organoheteryl; and
a is an integer from 1 to 60.

7. The method for preparing an optoelectronic device according to claim 6,
wherein R⁷, R⁸ and R⁹ in formula (III) are independently from each other selected from the group consisting of hydrogen, alkyl having 1 to 40 carbon atoms, alkenyl having 2 to 40 carbon atoms and aryl having 6 to 30 carbon atoms.

8. The method for preparing an optoelectronic device according to claim 1,
wherein the Lewis acid curing catalyst is represented by formula (1):
MLₓ (1)
wherein M is a member of the element groups 8, 9, 10, 11 and 13 of the periodic table;
L is a ligand which is at each occurrence selected independently from the group consisting of anionic ligands, neutral ligands and radical ligands; and
x is an integer from 2 to 6.

9. The method for preparing an optoelectronic device according to claim 8,
wherein M is selected from the list consisting of Fe, Ru, Os, Co, Rh, Ir, Ni, Pd, Pt, Cu, Ag, Au, B, Al, Ga, In and Tl.

10. The method for preparing an optoelectronic device according to claim 1,
wherein the curing in step (b) is carried out at elevated temperature.

11. An optoelectronic device,
obtainable by the method according to claim 1.

12. A crosslinkable polymer formulation comprising:
a polymer, and
a Lewis acid curing catalyst;
characterized in that the polymer is a polysiloxazane which contains a repeating unit M¹ and a repeating unit M³, wherein the repeating unit M¹ is represented by formula (I) and the repeating unit M³ is represented by formula (III):
-[—SiR¹R²—NR³—]- (I)
[—SiR⁷R⁸—[O—SiR⁷R⁸-]ₐ-NR⁹—]- (III)
wherein R¹, R², R³, R⁷, R⁸ and R⁹ are independently from each other selected from the group consisting of hydrogen, organyl and organoheteryl, and a is an integer from 1 to 60.

13. The crosslinkable polymer formulation according to claim 12,
wherein R¹, R², R³, R⁷, R⁸ and R⁹ are independently from each other selected from the group consisting of hydrogen, alkyl having 1 to 40 carbon atoms, alkenyl having 2 to 40 carbon atoms and aryl having 6 to 30 carbon atoms.

14. The crosslinkable polymer formulation according to claim 12,
characterized in that the Lewis acid curing catalyst is represented by formula (1):
MLₓ (1)
wherein M is a member of the element groups 8, 9, 10, 11 and 13 of the periodic table;
L is a ligand which is at each occurrence selected independently from the group consisting of anionic ligands, neutral ligands and radical ligands; and
x is an integer from 2 to 6.

15. The crosslinkable polymer formulation according to claim 12,
wherein M is selected from the list consisting of Fe, Ru, Os, Co, Rh, Ir, Ni, Pd, Pt, Cu, Ag, Au, B, Al, Ga, In and Tl.

16. A method for preparing an article comprising a crosslinked polymer material as technical coating which is prepared from a crosslinkable polymer formulation according to claim 12,
wherein the method comprises the following steps:
(a) applying the crosslinkable polymer formulation to a support; and
(b) curing said crosslinkable polymer formulation.

17. Article obtainable by the process according to claim 16.
